(19) United States
(12) Patent Application Publication
(10) Pub. No.: US 2016/0181242 A1
(43) Pub. Date: Jun. 23, 2016

(54) PASSIVE DEVICE AND MANUFACTURING METHOD THEREOF

(71) Applicant: Korea Electronics Technology Institute, Seongnam-si (KR)

(72) Inventors: Jong Min YOOK, Seongnam-si (KR); Jun Chul KIM, Seongnam-si (KR); Dong Su KIM, Seongnam-si (KR); Se Hoon PARK, Seongnam-si (KR); Jong In RYU, Seoul (KR); Jong Chul PARK, Suwon-si (KR)

(73) Assignee: Korea Electronics Technology Institute, Seongnam-si (KR)

(21) Appl. No.: 14/960,501

(22) Filed: Dec. 7, 2015

(30) Foreign Application Priority Data
Dec. 23, 2014 (KR) 10-2014-0187007
Sep. 7, 2015 (KR) 10-2015-0126058

(51) Int. Cl. H01L 27/07; H01L 49/02

(52) U.S. Cl. CPC H01L 27/0744; H01L 28/10; H01L 27/0788; H01L 28/60

(57) ABSTRACT

The present invention relates to a passive device and manufacturing method thereof. A capacitor according to the present invention includes: a capacitor thin film pattern formed on the upper surface of a substrate; a plurality of trenches formed by etching the substrate formed with the capacitor thin film pattern which defines the unit area of the capacitor; an insulation layer, which fills the trench, formed with capacitor interconnection holes for exposing the metal layers formed in the substrate and constituting the capacitor; and a plurality of capacitor electrode interconnection wires formed by filling the capacitor interconnection holes with a conductive material, wherein the lower surface of the substrate is being polished in a way that the insulation layer formed in the trenches is exposed.

### CROSS-REFERENCE TO RELATED PATENT APPLICATION

This U.S. non-provisional patent application claims priority under 35 U.S.C. §119 of Korean Patent Application No. 10-2014-0187007 filed on Dec. 23, 2014 and No. 10-2015-0126058 filed on Sep. 7, 2015 in the Korean Patent Office, the entire contents of which are hereby incorporated by reference.

### BACKGROUND

1. Technical Field

The present invention relates to a passive device and manufacturing method thereof. More specifically, the present invention relates to a passive device based on a lossy silicon substrate and manufacturing method thereof, wherein the electrical loss is being cut off by fundamentally blocking the path of electrical leakage towards the neighboring devices, and the electrical characteristics in the high frequency region is significantly improved.

2. Description of the Related Art

Generally, silicon substrates are commonly used due to the merits in the aspects of cost in spite of lossy characteristics thereof having significantly low electrical isolation coefficient. However, there is a problem that the electrical performance of the passive device, being implemented on a silicon substrate for an integrated circuit, is highly degraded.

Hereinafter, the problems of a passive device implemented on a silicon substrate having lossy characteristics will be separately described for a metal-insulator-metal (MIM) capacitor and a spiral inductor which are commonly used for designing, manufacturing, and the like of an RFIC.

FIG. 1 illustrates an MIM capacitor of the prior art.

Referring to FIG. 1, in order to reduce the electrical loss of the lossy silicon substrate, the MIM capacitor is manufactured in the form of a thin film structure under the state wherein a substrate insulation layer such as SiO₂ layer, SiNₓ layer is formed on the surface of the substrate, that is, in the lower portion where the passive device is to be formed.

The substrate insulation layer has to be formed to have a thickness less than few micrometers considering the process unit cost and the wafer bending, however, such thickness is not enough for sufficient electrical insulation of the passive device from the silicon substrate whose lower portion has lossy characteristics.

Thus, when integrating an MIM capacitor having a relatively large capacitance in a high frequency circuit, there is a problem that since the lower electrode (first metal layer of FIG. 1) having a large area and constituting the MIM capacitor is formed on the silicon substrate having lossy characteristics, a very high electrical loss is occurring thereby.

FIG. 2 illustrate a spiral inductor of the prior art.

Referring to FIG. 2, the spiral inductor of the prior art has a structure which includes a silicon substrate having lossy characteristics, a spiral inductor thin film pattern formed on the silicon substrate, and an insulation layer formed on the inductor thin film pattern and the substrate.

According to such spiral inductor of the prior art, there is a problem that a significant level of electrical leak is occurring since the silicon substrate located in the lower portion of the inductor thin film pattern has lossy characteristics. For example, an inductor having few nH level inductance and being integrated into a CMOS circuit typically has a Q factor of less than 10, and such low Q factor of the inductor degrades the electrical performance of the circuit and increases power consumption.

### PATENT LITERATURE

Korea Patent Publication No. 10-1999-0016810 (Date of publication: Mar. 15, 1999, Title: The capacitor manufacturing method of the semiconductor device);

Korea Patent Publication No. 10-2004-0086705 (Date of publication: Oct. 12, 2004, Title: Method for manufacturing capacitor in a semiconductor device);

Korea Patent Publication No. 10-2002-0014225 (Date of publication: Feb. 25, 2002, Title: Integrated device having insulator layer in trench overlapped with fine inductor and method for forming the same);

Korea Patent Publication No. 10-2004-0024121 (Date of publication: Mar. 20, 2004, Title: Inductor using in Radio Frequency Integrated Circuit); and

Korea Patent Publication No. 10-2006-0008045 (Date of publication: Jan. 26, 2006, Title: Method for forming inductor of semiconductor device)

### SUMMARY

A technical objective of the present invention is to provide a passive device and a manufacturing method thereof, wherein insulation material is filled into the trenches formed in the substrate located in the lower side of the passive device; then, the lower surface of the substrate, that is, the opposite side surface facing the upper surface of the substrate wherein the passive device is formed, is polished until the insulation layer is exposed; and the substrate becomes a fully isolated structure thereby; and the electrical loss is being cut off by fundamentally blocking the path of electrical leakage towards the neighboring devices; and the electrical characteristics in the high frequency region is significantly improved.

Another technical objective of the present invention is to provide a passive device and a manufacturing method thereof, wherein the level of the electrical performance, including Q factor, of the passive device manufactured in a low price lossy silicon substrate can be similarly maintained to that of the passive device manufactured in the expensive semi-insulating substrate such as a GaAs substrate.

Yet another technical objective of the present invention is to provide a passive device and a manufacturing method thereof, wherein

the electrical loss characteristic of a passive device in a high frequency circuit based on silicon substrate is significantly enhanced, thereby enhancing the characteristics of the overall system IC.

Still yet another technical objective of the present invention is to provide a passive device and a manufacturing method thereof which enables the implementation of a ‘system on a chip (SoC)’ wherein all RF circuits are integrated.

Yet still another technical objective of the present invention is to provide a passive device and a manufacturing method thereof which enables mass production of large diameter ‘integrated passive devices (IPDs)’ and interposers based on a lossy silicon substrate for high frequency package applications.

A capacitor according to the present invention for solving such technical problems is characterized in that and includes: a capacitor thin film pattern formed on one surface (e.g., the upper surface) of a substrate; a plurality of trenches formed by etching the substrate formed with the capacitor thin film pattern so as to define the unit area of the capacitor; an insulation layer, which fills the trenches, formed with a plurality of capacitor interconnection holes for exposing the metal layers formed in the substrate and constituting the capacitor; and a plurality of capacitor electrode interconnection wires formed by filling the capacitor interconnection holes with a conductive material, wherein the other surface (e.g., the lower surface) of the substrate is polished in a way that the insulation layer formed in the trenches is exposed.

The capacitor according to the present invention is characterized in that

the substrate is a silicon material, and a lower insulation layer is formed between the one side of the substrate and the capacitor thin film pattern.

A method for manufacturing a capacitor according to the present invention includes the steps of: forming a capacitor thin film pattern wherein the capacitor thin film pattern is formed on one surface (e.g., the upper surface) of a substrate; forming a plurality of trenches which define a unit area of the capacitor by etching the substrate wherein the capacitor thin film pattern is formed; forming an insulation layer wherein the insulation layer is formed in the trenches and on the substrate; forming a plurality of capacitor interconnection holes on the insulation layer so that the metal layers constituting the capacitor are exposed; forming a plurality of capacitor electrode interconnection wires by filling the capacitor interconnection holes with a conductive material; and polishing the other surface (e.g., the lower surface) of the substrate so that the insulation layer formed in the trenches is exposed.

The method for manufacturing a capacitor according to the present invention is characterized in that the substrate is a silicon material, and a lower insulation layer is formed between one surface (e.g., the upper surface) of the substrate and the capacitor thin film pattern.

The method for manufacturing a capacitor according to the present invention is characterized in that in the step of forming an insulation layer, the insulation layer is formed in the trenches and the substrate using a method of organic lamination, spin coating, or chemical vapor deposition.

A passive device including a capacitor and an inductor according to one aspect of the present invention is characterized in that and includes: a capacitor thin film pattern and a thin film metal pattern for the inductor interconnection wires formed on one surface (e.g., the upper surface) of a substrate; a plurality of trenches formed by etching the substrate wherein the capacitor thin film pattern and the thin film metal pattern are formed so that the unit areas of the capacitor and the inductor are defined thereby; an insulation layer which fills the trenches and formed on the substrate, wherein a plurality of capacitor interconnection holes for exposing the metal layers constituting the capacitor, and a plurality of inductor interconnection holes for exposing the thin film metal pattern for the inductor interconnection wires, are formed; a plurality of capacitor electrode interconnection wires formed by filling the capacitor interconnection holes formed in the insulation layer with a conductive material; and an inductor thin film pattern comprising conductive material formed on a top surface of the insulation layer and in the inductor interconnection holes formed in the insulation layer, wherein the other surface (e.g., the lower surface) of the substrate is polished so that the insulation layer formed in the trenches is exposed.

The passive device including a capacitor and an inductor according to one aspect of the present invention is characterized in that the substrate is a silicon material, and a lower insulation layer is formed between one surface (e.g., the upper surface) of the substrate and the capacitor thin film pattern and the thin film metal pattern for the inductor interconnection wires.

The passive device including a capacitor and an inductor according to one aspect of the present invention is characterized in that the inductor thin film pattern formed in the surface of the insulation layer has the shape of a spiral.

A method for manufacturing a passive device including a capacitor and an inductor according to one aspect of the present invention is characterized in that and includes the steps of: forming a capacitor thin film pattern and a thin film metal pattern for the inductor interconnection wires on one surface (e.g., the upper surface) of a substrate; forming a plurality of trenches which define the unit areas of the capacitor and the inductor by etching the substrate wherein the capacitor thin film pattern and the thin film metal pattern for the inductor interconnection wires are formed; forming an insulation layer in the trenches and the substrate; forming a plurality of capacitor interconnection holes in the insulation layer so that the metal layers constituting the capacitor are exposed, and a plurality of inductor interconnection holes in the insulation layer so that the thin film metal pattern for the inductor interconnection wires are exposed; forming a plurality of capacitor electrode interconnection wires by filling the capacitor interconnection holes with a conductive material; forming an inductor thin film pattern by filling the inductor interconnection holes formed in the insulation layer with a conductive material; and polishing the other surface (e.g., the lower surface) of the substrate so that the insulation layer formed in the trenches is exposed.

The method for manufacturing a passive device including a capacitor and an inductor according to one aspect of the present invention is characterized in that the substrate is a silicon material, and a lower insulation layer is formed between one surface (e.g., the upper surface) of the substrate and the capacitor thin film pattern and the thin film metal pattern for the inductor interconnection wires.

The method for manufacturing the passive device including a capacitor and an inductor according to one aspect of the present invention is characterized in that in the step of forming an insulation layer, the insulation layer is formed in the trenches and on the substrate using a method of organic lamination, spin coating, or chemical vapor deposition.

The method for manufacturing the passive device including a capacitor and an inductor according to one aspect of the present invention is characterized in that the step of forming a plurality of capacitor electrode interconnection wires and the step of forming an inductor thin film pattern are performed by the same process.

The method for manufacturing the passive device including a capacitor and an inductor according to one aspect of the present invention is characterized in that the inductor thin film pattern formed in the surface of the insulation layer in the step of forming the inductor thin film pattern has the shape of a spiral.

An inductor according to the present invention is characterized in that and includes: an inductor thin film pattern on one surface (e.g., the upper surface) of a substrate; a plurality of trenches formed in the substrate in a way that they surround the inductor thin film pattern and correspond to the inductor thin film pattern; and an insulation layer formed in the trenches and on the substrate and the inductor thin film pattern, wherein the other surface (e.g., the lower surface) of the substrate is polished so that the insulation layer formed in the trenches is exposed.

The inductor according to the present invention is characterized in that the substrate is a silicon based substrate having lossy characteristics.

The inductor according to the present invention is characterized in that the inductor thin film pattern has the shape of a spiral.

The inductor according to the present invention is characterized in that the trenches are formed by etching the substrate using the inductor thin film pattern as a mask.

The inductor according to the present invention is characterized in that a plurality of inductor electrode interconnection wires, which are connected to the inductor thin film pattern, is further included.

A method for manufacturing an inductor according to the present invention includes the steps of: forming an inductor thin film pattern on one surface (e.g., the upper surface) of a substrate; forming a plurality of trenches surrounding the inductor thin film pattern and corresponding to the inductor thin film pattern are formed in the substrate by etching the substrate using the inductor thin film pattern as a mask;

forming an insulation layer in the trenches and on the substrate and the inductor thin film pattern; and polishing the other surface (e.g., the lower surface) of the substrate so that the insulation layer formed in the trenches is exposed.

The method for manufacturing an inductor according to the present invention is characterized in that the substrate is a silicon based substrate having lossy characteristics.

The method for manufacturing an inductor according to the present invention is characterized in that the inductor thin film pattern has the shape of a spiral.

The method for manufacturing an inductor according to the present invention is characterized in that in the step of forming an insulation layer, the insulation layer is formed using a method of organic lamination, spin coating, molding, or screen printing.

The method for manufacturing an inductor according to the present invention further includes: forming a plurality of interconnection holes so that the inductor thin film pattern is exposed on the insulation layer; and forming a plurality of electrode interconnection wires by filling the inductor interconnection holes with a conductive material are further included.

A passive device including a capacitor and an inductor according to another aspect of the present invention is characterized in that and further includes: a capacitor thin film pattern and an inductor thin film pattern formed on one surface (e.g., the upper surface) of a substrate; a plurality of trenches including a plurality of first trenches formed on the substrate surrounding the capacitor thin film pattern, and a plurality of second trenches formed on the substrate surrounding the inductor thin film pattern and corresponding to the inductor thin film pattern; and an insulation layer formed in the trenches and on the substrate and the capacitor thin film pattern and the inductor thin film pattern, wherein the other surface (e.g., the lower surface) of the substrate is polished so that the insulation layer formed in the trenches is exposed.

The passive device including a capacitor and an inductor according to another aspect of the present invention is characterized in that the substrate is a silicon based substrate having lossy characteristics.

The passive device including a capacitor and an inductor according to another aspect of the present invention is characterized in that the inductor thin film pattern has the shape of a spiral.

The passive device including a capacitor and an inductor according to another aspect of the present invention is characterized in that the second trenches are formed by etching the substrate using the inductor thin film pattern as a mask.

The passive device including a capacitor and an inductor according to another aspect of the present invention is characterized in that the capacitor interconnection holes for exposing the capacitor thin film pattern and the inductor interconnection holes for exposing the inductor thin film pattern are formed in the insulation layer; and a plurality of capacitor electrode interconnection wires are formed in the capacitor interconnection holes, and a plurality of inductor electrode interconnection wires are formed in the inductor interconnection holes.

A method for manufacturing a passive device including a capacitor and an inductor according to another aspect of the present invention is characterized in that and includes: forming a capacitor thin film pattern and an inductor thin film pattern on one surface (e.g., the upper surface) of a substrate; forming a plurality of trenches wherein a plurality of first trenches surrounding the capacitor thin film pattern are formed in the substrate, a plurality of second trenches corresponding the inductor thin film pattern and surrounding the inductor thin film pattern are formed using the inductor thin film pattern as a mask; forming an insulation layer in the trenches and on the substrate, the capacitor thin film pattern and the inductor thin film pattern; and polishing the other surface (e.g., the lower surface) of the substrate so that the insulation layer formed in the trenches is exposed.

The method for manufacturing a passive device including a capacitor and an inductor according to another aspect of the present invention is characterized in that the substrate is a silicon based substrate having lossy characteristics.

The method for manufacturing a passive device including a capacitor and an inductor according to another aspect of the present invention is characterized in that the inductor thin film pattern has the shape of a spiral.

The method for manufacturing a passive device including a capacitor and an inductor according to another aspect of the present invention is characterized in that in the step of forming an insulation layer, the insulation layer is formed using a method of organic lamination, spin coating, molding, or screen printing.

The method for manufacturing a passive device including a capacitor and an inductor according to another aspect of the present invention is characterized in that and includes: forming capacitor interconnection holes so that the capacitor thin film pattern is exposed, and inductor interconnection holes so that the inductor thin film pattern is exposed on the insulation layer; and forming a plurality of electrode interconnection wires wherein a plurality of capacitor electrode interconnection wires are formed by filling the capacitor interconnection holes with a conductive material, and a plurality of electrode interconnection wires are formed by filling the inductor interconnection holes with a conductive material.

### Advantageous Effects

According to the present invention, there is an effect of providing a passive device and a manufacturing method thereof, wherein insulation material is filled into the trenches formed in the substrate located in the lower side of the passive device; then, the other surface (e.g., the lower surface) of the substrate, that is, the opposite side surface facing one surface (e.g., the upper surface) of the substrate wherein the passive device is formed, is polished until the insulation layer is exposed; and the substrate becomes a fully isolated structure thereby; and the electrical loss is cut off by fundamentally blocking the path of electrical leakage towards the neighboring devices; and the electrical characteristics in the high frequency region is significantly improved.

Besides, there is an effect of providing a passive device and a manufacturing method thereof, wherein the level of the electrical performance, including Q factor, of the passive device manufactured in a low price lossy silicon substrate can be similarly maintained to that of the passive device manufactured in the expensive semi-insulating substrate such as a GaAs substrate.

Moreover, there is an effect of providing a passive device and a manufacturing method thereof, wherein the electrical loss characteristic of a passive device in a high frequency circuit based on silicon substrate is significantly enhanced, thereby enhancing the characteristics of the overall system IC.

Furthermore, there is an effect of providing a passive device and a manufacturing method thereof which enables the implementation of a ‘system on a chip (SoC)’ wherein all RF circuits are integrated.

Furthermore, there is an effect of providing a passive device and a manufacturing method thereof which enables mass production of large diameter ‘integrated passive devices (IPDs)’ and interposers based on a lossy silicon substrate for high frequency package applications.

### BRIEF DESCRIPTION OF DRAWINGS

FIG. 1 is a view illustrating a Metal Insulator Metal (MIM) capacitor of the prior art.

FIG. 2 is a view illustrating a spiral inductor of the prior art.

FIG. 3 is a cross-sectional view of a capacitor according to an exemplary embodiment of the present invention.

FIG. 4 is a plan view of a capacitor according to an exemplary embodiment of the present invention.

FIG. 5 is a flow diagram of a method for manufacturing a capacitor according to an exemplary embodiment of the present invention.

FIGS. 6 to 11 are the cross-sectional views illustrating the processes of a method for manufacturing a capacitor according to an exemplary embodiment of the present invention.

FIG. 12 is a cross-sectional view of a passive device including a capacitor and an inductor according to the first exemplary embodiment of the present invention.

FIG. 13 is a plan view of a passive device including a capacitor and an inductor according to the first exemplary embodiment of the present invention.

FIG. 14 is a flow diagram of a method for manufacturing a passive device including a capacitor and an inductor according to the first exemplary embodiment of the present invention.

FIGS. 15 to 20 are the cross-sectional views illustrating the processes of a method for manufacturing a passive device including a capacitor and an inductor according to the first exemplary embodiment of the present invention.

FIGS. 21 and 22 are the graphs comparing the experimental values of scattering parameters (S-parameter) of a capacitor of the prior art and a capacitor according to an exemplary embodiment of the present invention both having cross-sectional area of 150×150 um².

FIGS. 23 and 24 are the graphs comparing the experimental values of scattering parameters (S-parameter) of a capacitor of the prior art and a capacitor according to an exemplary embodiment of the present invention both having cross-sectional area of 300×300 um².

FIG. 25 is a cross-sectional view of an inductor according to an exemplary embodiment of the present invention.

FIG. 26 is a plan view of an inductor according to an exemplary embodiment of the present invention.

FIG. 27 is a process flow diagram of a method for manufacturing an inductor according to an exemplary embodiment of the present invention.

FIGS. 28 to 33 are the cross-sectional views illustrating the processes of a method for manufacturing an inductor according to an exemplary embodiment of the present invention.

FIG. 34 is a cross-sectional view of a passive device including a capacitor and an inductor according to the second exemplary embodiment of the present invention.

FIG. 35 is a plan view of a passive device including a capacitor and an inductor according to the second exemplary embodiment of the present invention.

FIG. 36 is a process flow diagram of a method for manufacturing a passive device including a capacitor and an inductor according to the second exemplary embodiment of the present invention.

FIGS. 37 to 42 are the cross-sectional views illustrating the processes of a method for manufacturing a passive device including a capacitor and an inductor according to the second exemplary embodiment of the present invention.

FIG. 43 is the graph comparing the experimental values of scattering parameters (S-parameter) of a passive device of the prior art and a passive device including a capacitor and an inductor according to the second exemplary embodiment of the present invention.

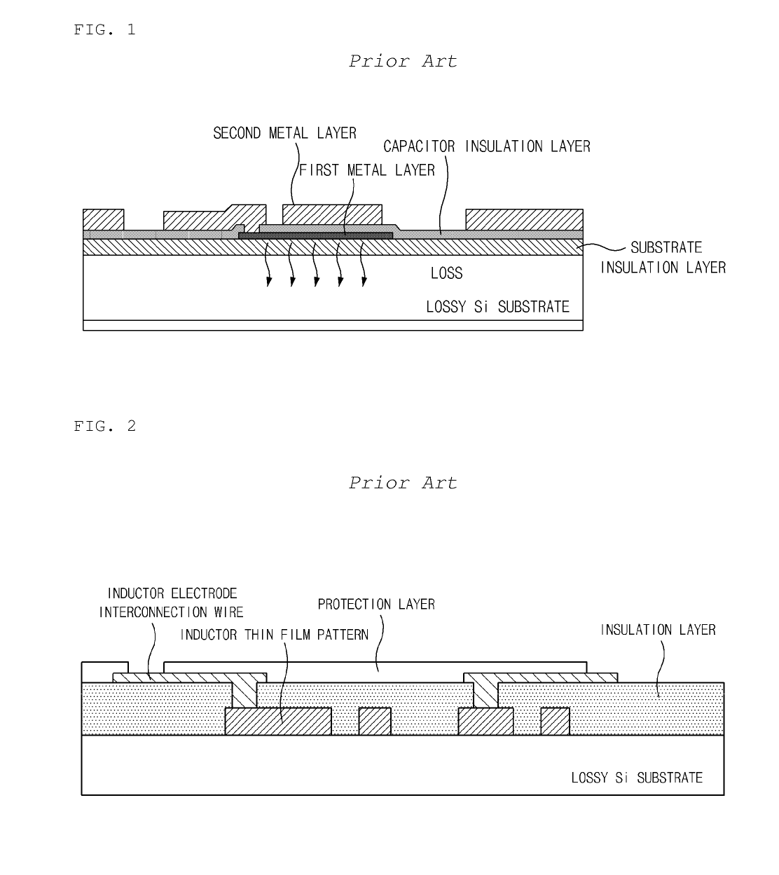

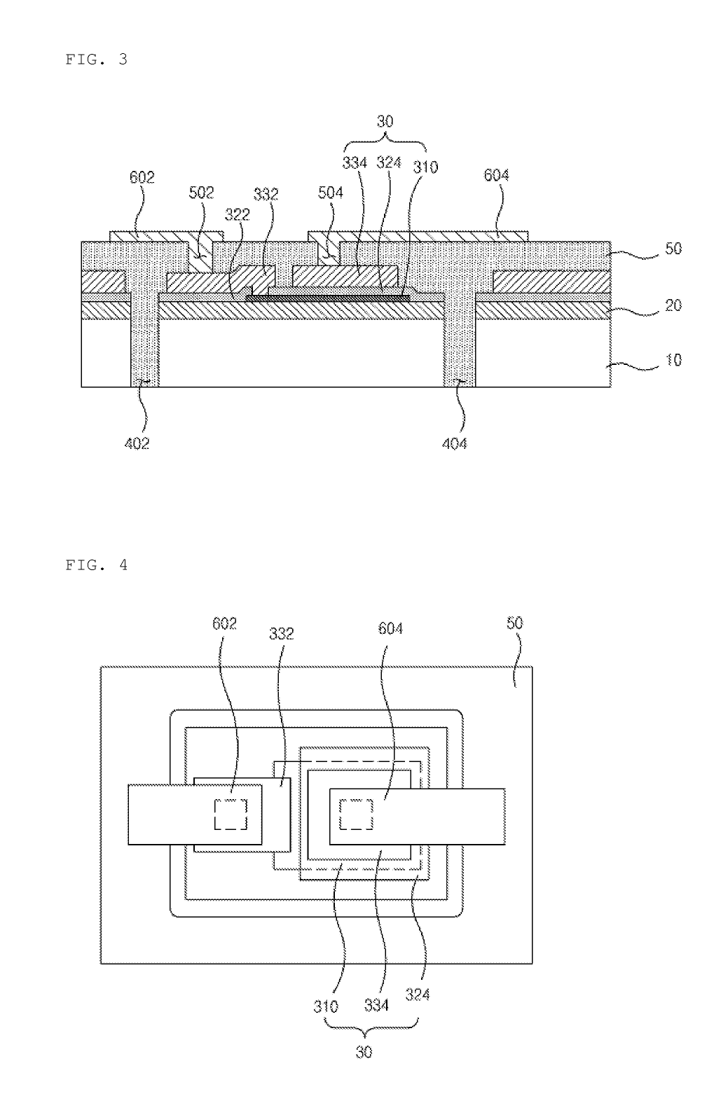

### DETAILED DESCRIPTION OF EMBODIMENTS

Specific structural or functional descriptions on the exemplary embodiments according to the concept of the present invention disclosed in the specification of the present invention are mere examples for the purpose of describing the exemplary embodiments according to the concept of the present invention; however, the inventive concept may be embodied in various different forms, and should not be construed as being limited only to the illustrated embodiments in the specification of the present invention.

Since various changes may be applied to the exemplary embodiments according to the concept of the present invention and have various forms, embodiments will be described in detail with reference to the following description and accompanying drawings. However, the exemplary embodiments according to the concept of the present invention should not be limited to the specific forms disclosed herein, but include all modifications and equivalents, or alternatives falling within the spirit and scope of the present invention.

It will be understood that, although the terms “first,” “second,” etc., may be used herein to describe various elements, these elements should not be limited by these terms. These terms are only used to distinguish one element from another element, for example, without departing from the scope of the claims according to the concept of the present invention. That is, a first element may be named as a second element, and similarly, a second element may be named as a first element.

It should be understood that when an element is referred to as being “connected to” or “coupled with” another element, it can be directly connected or coupled to the other element, or intervening elements may be present. In contrast, when an element is referred to as being “directly connected to” or “directly coupled with” another element, it should be understood that there are no intervening elements present. Other expressions describing the relationships between the elements, for example, “between˜” and “directly between˜,” or “neighboring˜” and “directly neighboring˜,” and the like should be understood in the same way.

The terminology used herein is for the purpose of describing particular embodiments only and is not intended to be limiting of the present inventive concept. As used herein, the singular forms are intended to include the plural forms as well, unless the context clearly indicates otherwise. It should be further understood that the terms “comprises” and/or “comprising,” when used in this specification, specify the presence of stated features, numerals, steps, operations, elements, components and/or combinations thereof, but do not preclude the presence or addition of one or more other features, numerals, steps, operations, elements, components, and/or combinations thereof.

Unless otherwise defined, all terms (including technical and scientific terms) used herein have the same meaning as commonly understood by one of ordinary skill in the art to which this inventive concept belongs. It should be further understood that terms, such as those defined in commonly used dictionaries, should be interpreted as having a meaning that is consistent with their meaning in the context of the relevant art and should not be interpreted in an idealized or overly formal sense unless expressly so defined herein.

Hereinafter, preferred exemplary embodiments of the present invention will be described in detail with reference to the accompanying drawings. Although preferred exemplary embodiments of the present invention will be described with a metal-insulator-metal (MIM) capacitor as an example, besides the MIM capacitor, the capacitor may be an interdigital capacitor, a silicon-insulator-silicon (SIS) capacitor, and a metal-insulator-semiconductor (MIS) capacitor.

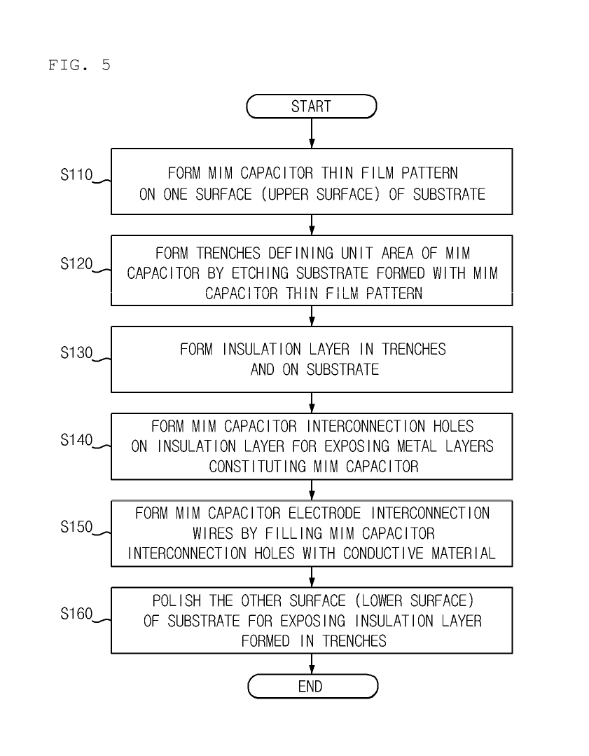

FIG. 3 is a cross-sectional view of a capacitor according to an exemplary embodiment of the present invention; and FIG. 4 is a plan view of a capacitor according to an exemplary embodiment of the present invention.

Referring to FIGS. 3 and 4, a capacitor according to an exemplary embodiment of the present invention includes: a substrate 10, a lower insulation layer 20, a capacitor thin film pattern 30, trenches 402, 404, an insulation layer 50, and a plurality of capacitor electrode interconnection wires 602, 604.

The substrate 10 may be a substrate of a silicon material having lossy characteristics.

The upper surface of the substrate 10 is the surface wherein a capacitor thin film pattern 30 which will be described later is being formed, while the lower surface of the substrate 10 is the opposite surface facing the upper surface.

The lower insulation layer 20 is formed in the upper surface of the substrate, and performs the function of reducing the electrical loss of the silicon having lossy characteristics. For example, such lower insulation layer 20 may be a silicon dioxide (SiO₂) or a silicon nitride (SiNₓ), and may be formed to have a thickness less than few microns considering the process unit cost and the wafer bending. Such lower insulation layer 20 is an optional element. That is, even without the lower insulation layer 20, as described hereinafter, trenches 402, 404 are formed in the substrate; and after filling the trenches 402, 404 with an insulation layer 50, the lower surface of the substrate 10 is polished in a way that the insulation layer 50 having been filled in the trenches 402, 404 is exposed; so that the electrical loss can be cut off by blocking the path of electrical leakage towards the neighboring unit devices; and accordingly, the electrical characteristics of a capacitor, which is a final product, are greatly enhanced.

The capacitor thin film pattern 30 is formed on one side of the substrate 10. For example, if the embodiment of the present invention includes a lower insulation layer 20, the capacitor thin film pattern 30 is formed on the upper surface of the lower insulation layer 20; and if the embodiment of the present invention does not include a lower insulation layer 20, the capacitor thin film pattern 30 is directly formed on one side of the substrate 30.

Such capacitor thin film pattern 30 is comprised of a first metal layer 310, a capacitor insulation layer 324, and a second metal layer 334. Since such structure is commonly used, the detailed description thereof will be omitted. The numerical symbol 322 represents an insulation layer being formed during the step of forming the insulation layer 324 of the capacitor, and the numerical symbol 322 represents a metal layer being formed during the step of forming the metal layer 334.

The trenches 402, 404 are formed by etching the substrate 10 wherein a capacitor thin film pattern 30 is formed so as to define the unit area of the capacitor according to the present invention. Since the purpose of the insulation layer 50 being filled in the trenches 402, 404 is to obtain the electrical insulation, it becomes more advantageous as the widths of the trenches 402, 404 are getting wider. For example, for a few GHz application range, a sufficient insulation can be obtained if the width of the trench is wider than about 10 μm.

The insulation layer 50 is formed on the substrate 10 filling the trenches 402, 404; and the metal layers constituting the capacitor, that is, a first metal layer 310 and the capacitor interconnection holes 502, 504 for exposing the second metal layer 334 are formed in the insulation layer 50.

The capacitor electrode interconnection wires 602, 604 are formed by filling the capacitor interconnection holes 502, 504 with a conductive material.

Meanwhile, a capacitor according to an exemplary embodiment of the present invention has a structure wherein the insulation layer 50 formed in the trenches 402, 404 is exposed by polishing the lower surface of the substrate 10, that is, the opposite side surface facing the upper surface of the substrate 10 wherein the capacitor thin film pattern 30 is formed. According to such structure, the electrical loss can be cut off by blocking the path of electrical leakage towards the neighboring unit devices; and accordingly, the electrical characteristics of the capacitor, which is a final product, are greatly enhanced. More specifically, the electrical loss characteristic of a capacitor in a high frequency circuit based on silicon substrate is significantly enhanced, thereby enhancing the characteristics of the overall system IC, enabling the implementation of a ‘system on a chip (SoC)’ wherein all RF circuits are integrated, and enabling mass production of large diameter ‘integrated passive devices (IPDs)’ and interposers based on a lossy silicon substrate for high frequency package applications.

FIG. 5 is a flow diagram of a method for manufacturing a capacitor according to an exemplary embodiment of the present invention; and FIGS. 6 to 11 are the cross-sectional views illustrating the processes of a method for manufacturing a capacitor according to an exemplary embodiment of the present invention.

Referring to FIG. 5, a method for manufacturing a capacitor according to an exemplary embodiment of the present invention includes the steps of: S110 for forming a capacitor thin film pattern, S120 for forming a plurality of trenches, S130 for forming an insulation layer, S140 for forming interconnection holes, S150 for forming a plurality of capacitor electrode interconnection wires, and S160 for substrate polishing.

Further referring to FIG. 6, in step S110 for forming a capacitor thin film pattern, forming process of a capacitor thin film pattern 30 on the upper surface of the substrate 10 is performed.

The substrate 10 may be a substrate of a silicon material having lossy characteristics. The upper surface of the substrate 10 is the surface wherein a capacitor thin film pattern 30 is being formed, while the lower surface of the substrate 10 is the opposite surface facing the upper surface.

Before forming the capacitor thin film pattern 30, forming process of a lower insulation layer 20 in the upper surface of the substrate 10 may be performed. Such lower insulation layer 20 performs the function of reducing the electrical loss of the silicon having lossy characteristics. For example, such lower insulation layer 20 may be a silicon dioxide (SiO₂) or a silicon nitride (SiNₓ), and may be formed to have a thickness less than few microns considering the process unit cost and the wafer bending. Such lower insulation layer 20 is an optional element. That is, even without the lower insulation layer 20, as described hereinafter, trenches 402, 404 are formed in the substrate; and after filling the trenches 402, 404 with an insulation layer 50, the lower surface of the substrate 10 is polished in a way that the insulation layer 50 having been filled in the trenches 402, 404 is exposed; so that the electrical loss can be cut off by blocking the path of electrical leakage towards the neighboring unit devices; and accordingly, the electrical characteristics of a capacitor, which is a final product, are greatly enhanced.

The capacitor thin film pattern 30 is formed on one side of the substrate 10. For example, if the embodiment of the present invention includes a step of forming a lower insulation layer 20, the capacitor thin film pattern 30 is formed on the upper surface of the lower insulation layer 20; and if the embodiment of the present invention does not include a step of forming a lower insulation layer 20, the capacitor thin film pattern 30 is directly formed on one side of the substrate 30.

Such capacitor thin film pattern 30 is formed through the processes of forming a first metal layer 310 patterned in the form of a thin film, a capacitor insulation layer 324, and a second metal layer 334 in a sequential manner. Since such processes are commonly used, the detailed description on these processes will be omitted.

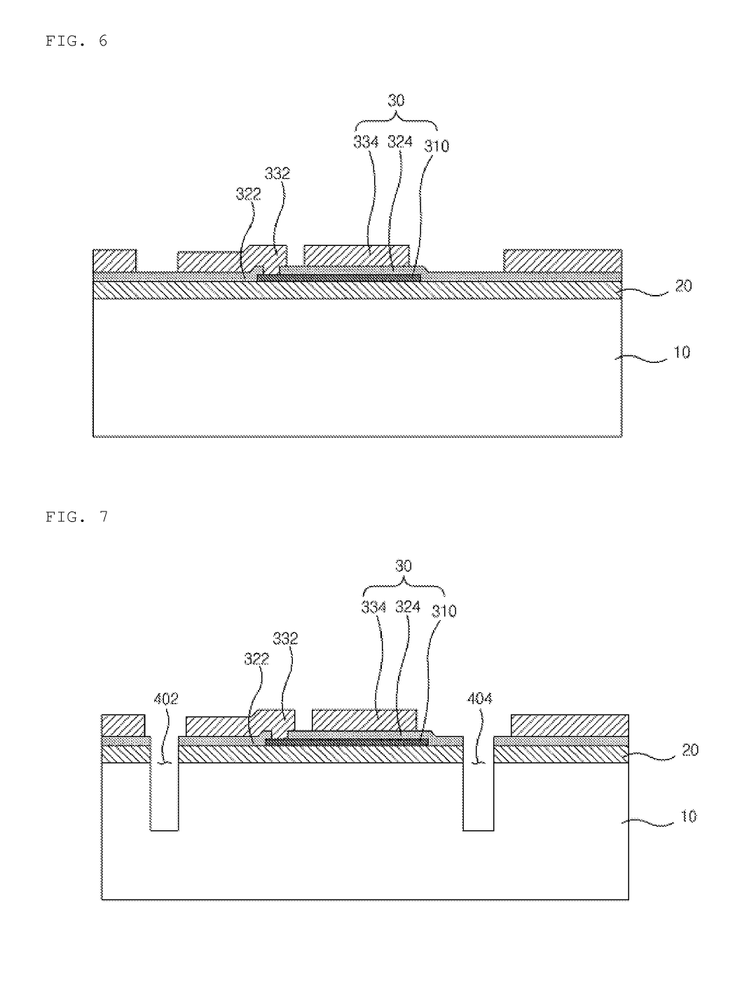

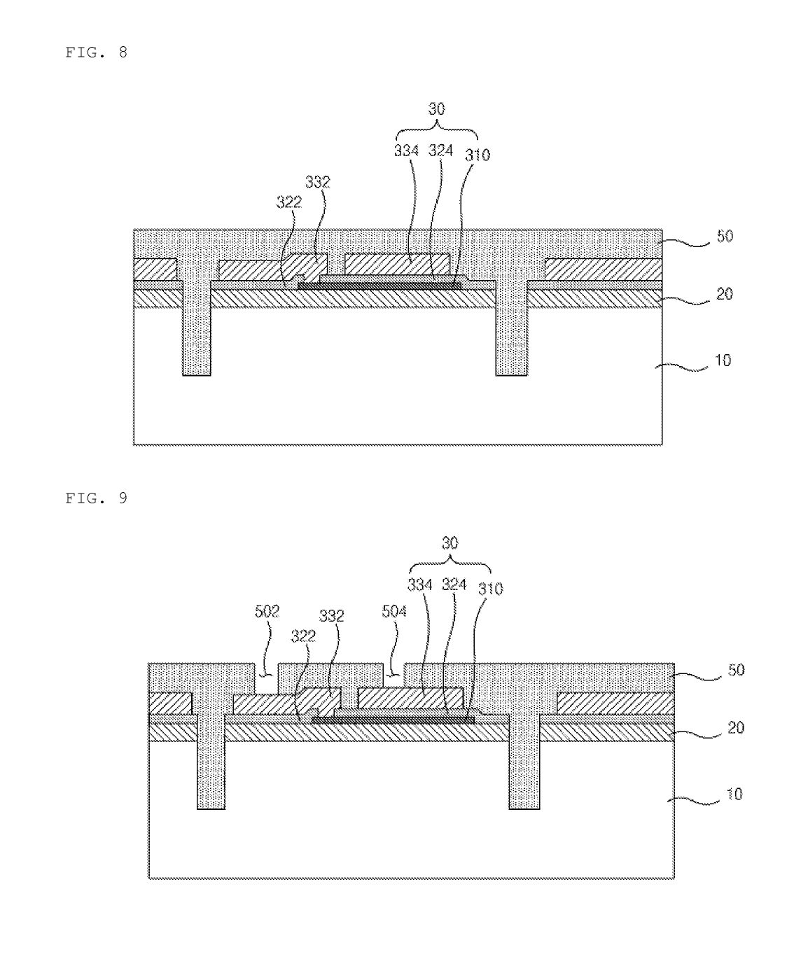

Further referring to FIG. 7, in step S120 for forming a plurality of trenches, forming process of trenches 402, 404 is performed for defining the unit area of the capacitor by etching the substrate 10 wherein the capacitor thin film pattern 30 is formed. Since the purpose of the insulation layer 50 being filled in the trenches 402, 404 through the step S130 for forming insulation layer which will be described later, is to obtain the electrical insulation, it becomes more advantageous as the widths of the trenches 402, 404 are getting wider. For example, for a few GHz application range, a sufficient insulation can be obtained if the width of the trench is wider than 10 μm.

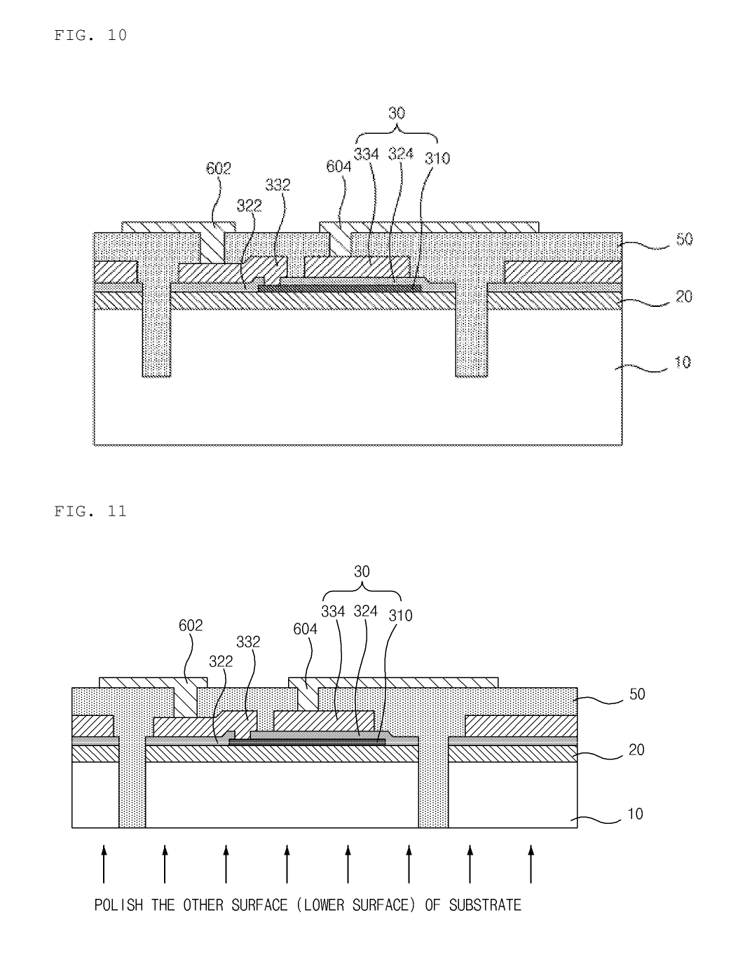

Further referring to FIG. 8, in step S130 for forming an insulation layer, processes of forming trenches 402, 404 and forming an insulation layer 50 in the substrate 10 are performed. For example, the step S130 for forming the insulation layer may be configured to form the insulation layer 50 in the trenches 402, 404 and on the substrate 10 by using a method of organic lamination, spin coating, or chemical vapor deposition. Although a method of organic lamination which is advantageous in the aspect of cost is desirable for forming the insulation layer 50, a method of spin coating or chemical vapor deposition may be applied depending on the widths and the depths of the trenches 402, 404.

Further referring to FIG. 9, in step S140 for forming interconnection holes, forming process of capacitor interconnection holes 502, 504 on the insulation layer 50 is performed so that the metal layers constituting the capacitor, that is, a first metal layer 310 and a second metal layer 334 are exposed.

Further referring to FIG. 10, in step S150 for forming a plurality of capacitor electrode interconnection wires, forming process of capacitor electrode interconnection wires 602, 604 is performed

Further referring to FIG. 11, in step S160 for substrate polishing, process of polishing the lower surface of the substrate 10 is performed so that the insulation layer 50 formed in the trenches 402, 404 is exposed. This process may be performed by chemical polishing or mechanical polishing.

Once the above described method for manufacturing a capacitor according to an exemplary embodiment of the present invention is performed, a structure is obtained wherein the insulation layer 50 formed in the trenches 402, 404 is exposed through polishing of the lower surface, that is, the opposite surface facing the upper surface of the substrate 10 wherein the capacitor thin film pattern 30 is formed. According to such structure, the electrical loss can be cut off by blocking the path of electrical leakage towards the neighboring unit devices; and accordingly, the electrical characteristics of a capacitor, which is a final product, are greatly enhanced. More specifically, the electrical loss characteristic of a capacitor in a high frequency circuit based on silicon substrate is significantly enhanced, thereby enhancing the characteristics of the overall system IC, enabling the implementation of a ‘system on a chip (SoC)’ wherein all RF circuits are integrated, and enabling mass production of large diameter ‘integrated passive devices (IPDs)’ and interposers based on a lossy silicon substrate for high frequency package applications. In addition, the electrical characteristics of the capacitor may be effectively enhanced through the simple processes of forming trenches and forming insulation layer, and substrate 10 polishing.

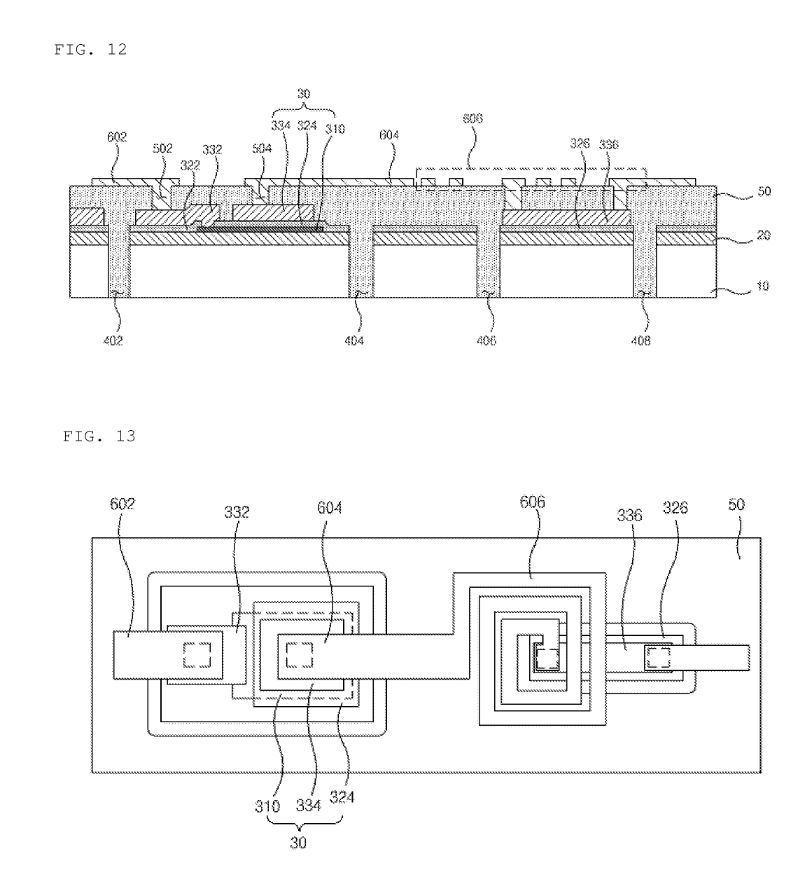

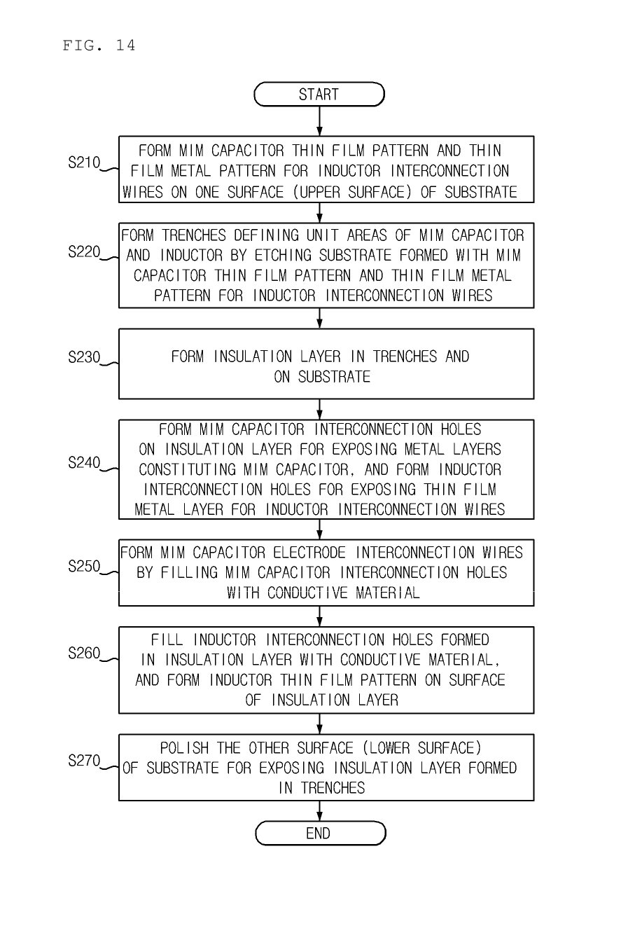

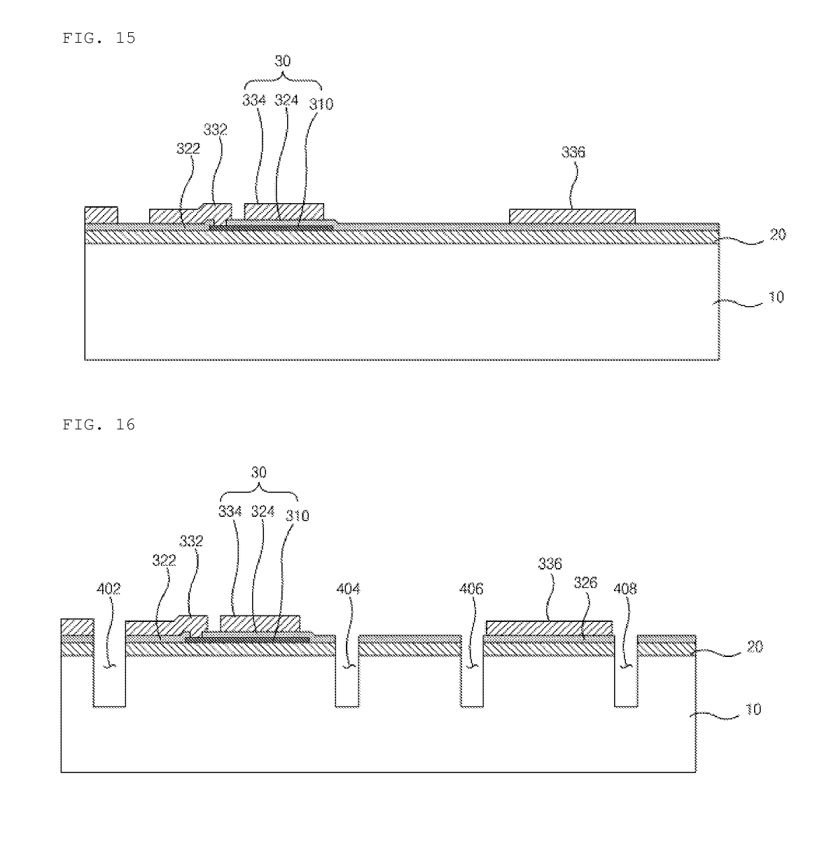

FIG. 12 is a cross-sectional view of a passive device including a capacitor and an inductor according to the first exemplary embodiment of the present invention; and FIG. 13 is a plan view of a passive device including a capacitor and an inductor according to the first exemplary embodiment of the present invention.

Referring to FIGS. 12 and 13, a passive device including a capacitor and an inductor according to an exemplary embodiment of the present invention includes: a substrate 10, a lower insulation layer 20, a capacitor thin film pattern 30, an inductor interconnection wire thin film metal pattern 336, a plurality of trenches 402, 404, 406, 408, an insulation layer 50, a plurality of capacitor interconnection wires 602, 604, and an inductor thin film pattern 606.

The substrate 10 may be a substrate of a silicon material having lossy characteristics. The upper surface of the substrate 10 is the surface wherein a capacitor thin film pattern 30 and an inductor thin film pattern 606 which will be described later are being formed, while the lower surface of the substrate 10 is the opposite surface facing the upper surface.

The lower insulation layer 20 is formed in the upper surface of the substrate, and performs the function of reducing the electrical loss of the silicon having lossy characteristics. For example, such lower insulation layer 20 may be a silicon dioxide (SiO₂) or a silicon nitride (SiNₓ), and may be formed to have a thickness less than few microns considering the process unit cost and the wafer bending. Such lower insulation layer 20 is an optional element. That is, even without the lower insulation layer 20, as described hereinafter, trenches 402, 404, 406, 408 are formed in the substrate; and after filling the trenches 402, 404, 406, 408 with an insulation layer 50, the lower surface of the substrate 10 is polished in a way that the insulation layer 50 having been filled in the trenches 402, 404, 406, 408 is exposed; so that the electrical loss can be cut off by blocking the path of electrical leakage towards the neighboring unit devices; and accordingly, the electrical characteristics of a passive device including a capacitor and an inductor, which is a final product, are greatly enhanced.

The capacitor thin film pattern 30 and the inductor interconnection wire thin film metal pattern 336 are formed on the upper surface of the substrate 10 and may be formed simultaneously through the same process.

For example, if the embodiment of the present invention includes a lower insulation layer 20, the capacitor thin film pattern 30 and the inductor interconnection thin film metal pattern 336 are formed on the upper surface of the lower insulation layer 20; and if the embodiment of the present invention does not include a lower insulation layer 20, the capacitor thin film pattern 30 and the inductor interconnection thin film metal pattern 336 are directly formed on the upper surface of the substrate 10.

The capacitor thin film pattern 30 is comprised of a first metal layer 310, a capacitor insulation layer 324, and a second metal layer 334. Besides, the inductor interconnection thin film metal pattern 336 may be formed together with the second metal layer 334 during the forming process of the second metal layer, and an inductor insulation layer 326 may be formed in the lower portion of the inductor interconnection thin film metal pattern 336. This inductor insulation layer 326 may be formed together with the capacitor insulation layer 324 during the forming process of the capacitor insulation layer.

The trenches 402, 404, 406, 408 are formed by etching the substrate 10 wherein a capacitor thin film pattern 30 and the inductor interconnection thin film metal pattern 336 are formed so as to define the unit areas of the capacitor and the inductor. Since the purpose of the insulation layer 50 being filled in the trenches 402, 404, 406, 408 is to obtain the electrical insulation, it becomes more advantageous as the widths of the trenches 402, 404, 406, 408 are getting wider. For example, for a few GHz application range, a sufficient insulation can be obtained if the width of the trenches 402, 404, 406, 408 is wider than about 10 μm.

The insulation layer 50 is formed on the substrate 10 filling the trenches 402, 404, 406, 408; and the metal layers constituting the capacitor, that is, a first metal layer 310 and the capacitor interconnection holes 502, 504 for exposing the second metal layer 334, and the inductor interconnection holes 506, 508 for exposing the inductor interconnection thin film metal pattern 336 are formed in the insulation layer 50.

The capacitor electrode interconnection wires 602, 604 are formed by filling the capacitor interconnection holes 502, 504 with a conductive material.

The inductor thin film pattern 606 is comprised of a conductive material formed on the insulation layer 50 and in the inductor interconnection holes 506, 508 formed in the surface of the insulation layer 50. The inductor thin film pattern 606 formed in the surface of the insulation layer 50 has the shape of a spiral.

Meanwhile, a passive device including a capacitor and an inductor according to the first exemplary embodiment of the present invention has a structure wherein the insulation layer 50 formed in the trenches 402, 404, 406, 408 is exposed through polishing of the lower surface, that is, the opposite surface facing the upper surface of the substrate 10 wherein the capacitor thin film pattern 30 and the inductor thin film pattern 606 are formed. According to such structure, the electrical loss can be cut off by blocking the path of electrical leakage towards the neighboring unit devices; and accordingly, the electrical characteristics of a passive device including a capacitor and an inductor, which is a final product, are greatly enhanced. More specifically, the electrical loss characteristic of a passive device in a high frequency circuit based on silicon substrate is significantly enhanced, thereby enhancing the characteristics of the overall system IC, enabling the implementation of a ‘system on a chip (SoC)’ wherein all RF circuits are integrated, and enabling mass production of large diameter ‘integrated passive devices (IPDs)’ and interposers based on a lossy silicon substrate for high frequency package applications.

FIG. 14 is a flow diagram of a method for manufacturing a passive device including a capacitor and an inductor according to the first exemplary embodiment of the present invention; and FIGS. 15 to 20 are the cross-sectional views illustrating the processes of a method for manufacturing a passive device including a capacitor and an inductor according to the first exemplary embodiment of the present invention.

Referring to FIG. 14, a method for manufacturing a passive device including a capacitor and an inductor according to the first exemplary embodiment of the present invention includes the steps of: step S210 for forming a thin film pattern, step S220 for forming a plurality of trenches, step S230 for forming an insulation layer, step S240 for forming a plurality of interconnection holes, step S250 for forming a plurality of capacitor electrode interconnection wires, a step for forming an inductor pattern 606, and step S270 for substrate polishing.

Further referring to FIG. 15, in step S210 for forming a thin film pattern, forming process of a capacitor thin film pattern 30 and an inductor interconnection metal pattern 336 on the upper surface of the substrate 10 is performed.

The substrate 10 may be a substrate of a silicon material having lossy characteristics. The upper surface of the substrate 10 is the surface wherein a capacitor thin film pattern 30 and an inductor interconnection metal pattern 336 are being formed, while the lower surface of the substrate 10 is the opposite surface facing the upper surface.

Before forming the capacitor thin film pattern 30 and an inductor interconnection metal pattern 336, process for forming a lower insulation layer 20 in the upper surface of the substrate 10 may be performed. Such lower insulation layer 20 performs the function of reducing the electrical loss of the silicon having lossy characteristics. For example, such lower insulation layer 20 may be a silicon dioxide (SiO₂) or a silicon nitride (SiNₓ), and may be formed to have a thickness less than few microns considering the process unit cost and the wafer bending. Such lower insulation layer 20 is an optional element. That is, even without the lower insulation layer 20, as described hereinafter, the trenches 402, 404, 406, 408 are formed in the substrate; and after filling the trenches 402, 404 with an insulation layer 50, the lower surface of the substrate 10 is polished in a way that the insulation layer 50 having been filled in the trenches 402, 404, 406, 408 is exposed; so that the electrical loss can be cut off by blocking the path of electrical leakage towards the neighboring unit devices; and accordingly, the electrical characteristics of a passive device including a capacitor and an inductor, which is a final product, are greatly enhanced.

The capacitor thin film pattern 30 and the inductor interconnection wire thin film metal pattern 336 are formed on the upper surface of the substrate 10 and may be formed simultaneously through the same process.

For example, if the embodiment of the present invention includes a lower insulation layer 20, the capacitor thin film pattern 30 and the inductor interconnection thin film metal pattern 336 are formed on the upper surface of the lower insulation layer 20 using the same process; and if the embodiment of the present invention does not include a lower insulation layer 20, the capacitor thin film pattern 30 and the inductor interconnection thin film metal pattern 336 are formed on one side of the substrate 10 using the same process.

The capacitor thin film pattern 30 is comprised of a first metal layer 310, a capacitor insulation layer 324, and a second metal layer 334. Besides, the inductor interconnection thin film metal pattern 336 may be formed together with the second metal layer 334 during the forming process of the second metal layer, and an inductor insulation layer 326 may be formed in the lower portion of the inductor interconnection thin film metal pattern 336. This inductor insulation layer 326 may be formed together with the capacitor insulation layer 324 during the forming process of the capacitor insulation layer.

Further referring to FIG. 16, in step S220 for forming a plurality of trenches, forming process of the trenches 402, 404, 406, 408 which define the unit areas of the capacitor and the inductor by etching the substrate 10 wherein the capacitor thin film pattern 30 and the inductor interconnection thin film metal pattern 336 are formed.

Since the purpose of the insulation layer 50 being filled in the trenches 402, 404, 406, 408 through the step S230 for forming insulation layer which will be described later, is to obtain the electrical insulation, it becomes more advantageous as the widths of the trenches 402, 404, 406, 408 are getting wider. For example, for a few GHz application range, a sufficient insulation can be obtained if the width of the trench is wider than 10 μm.

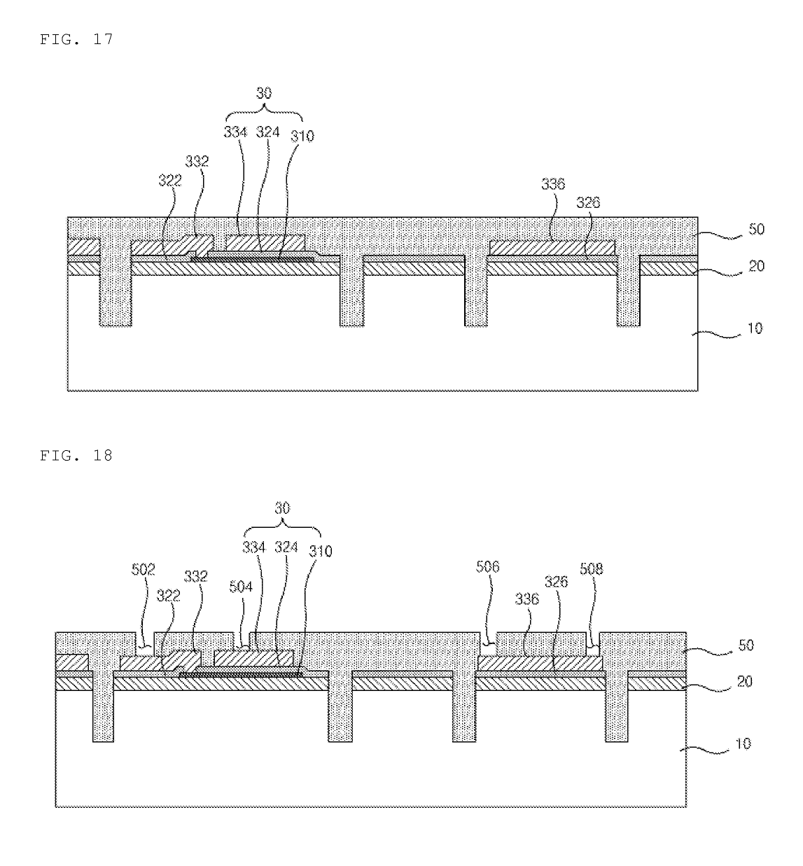

Further referring to FIG. 17, in step S130 for forming an insulation layer, processes of forming trenches 402, 404, 406, 408 and forming an insulation layer 50 in the substrate 10 are performed. For example, the step S230 for forming the insulation layer may be configured to form the insulation layer 50 in the trenches 402, 404, 406, 408 and on the substrate 10 by using a method of organic lamination, spin coating, or chemical vapor deposition. Although a method of organic lamination which is advantageous in the aspect of cost is desirable for forming the insulation layer 50, a method of spin coating or chemical vapor deposition may be applied depending on the widths and the depths of the trenches 402, 404, 406, 408.

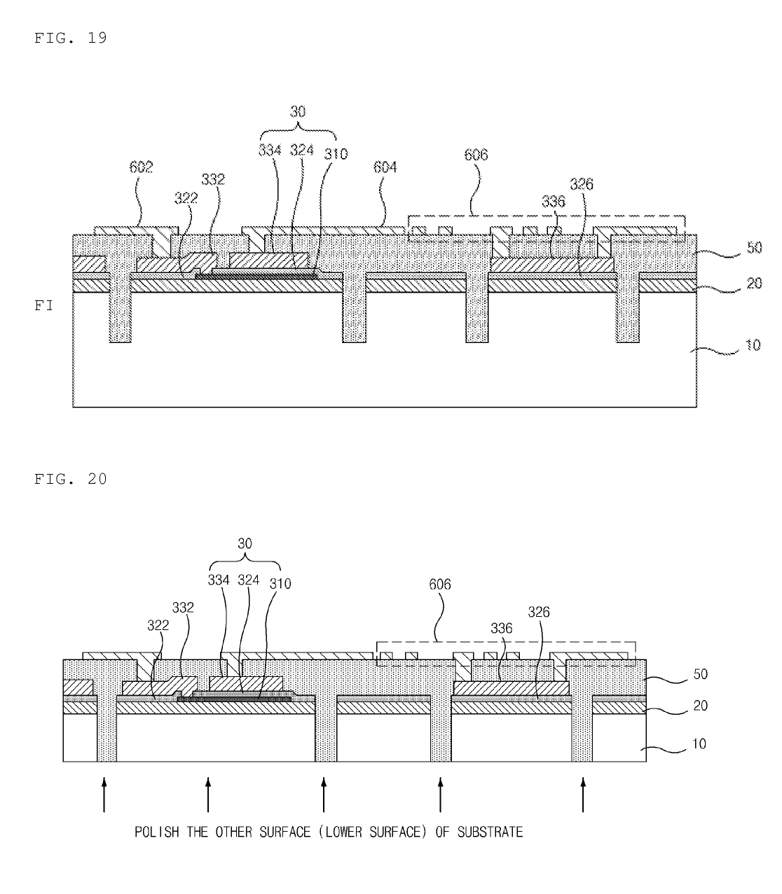

Further referring to FIG. 18, in step S240 for forming interconnection holes, forming process of capacitor interconnection holes 502, 504 on the insulation layer 50 is performed so that the metal layers constituting the capacitor, that is, a first metal layer 310 and a second metal layer 334 are exposed; and forming process of inductor interconnection holes 506, 508 is performed so that the inductor interconnection thin film metal layers are exposed.

Further referring to FIG. 19, in step S250 for forming a plurality of capacitor electrode interconnection wires, forming process of the capacitor electrode interconnection wires 602, 604 is performed by filling the capacitor interconnection holes 502, 504 with a conductive material; and in step S260 for forming an inductor thin film pattern, the inductor interconnection holes 506, 508 formed in the insulation layer 50 are being filled with a conductive material, and forming process of the inductor thin film pattern 606 having the shape of, for example, a spiral is being performed.

Further referring to FIG. 20, in step S270 for substrate polishing, process of polishing the lower surface of the substrate 10 is performed so that the insulation layer 50 formed in the trenches 402, 404, 406, 408 is exposed. This process may be performed by chemical polishing or mechanical polishing.

Once the method, as previously described in detail, for manufacturing a passive device including a capacitor and an inductor according to the first exemplary embodiment of the present invention is performed, a structure is obtained wherein the insulation layer 50 formed in the trenches 402, 404, 406, 408 is exposed through polishing of the lower surface, that is, the opposite surface facing the upper surface of the substrate 10 wherein the capacitor thin film pattern 30 and the inductor thin film pattern 606 is formed. According to such structure, the electrical loss can be cut off by blocking the path of electrical leakage towards the neighboring unit devices; and accordingly, the electrical characteristics of a passive device including a capacitor, which is a final product, are greatly enhanced. More specifically, the electrical loss characteristic of a passive device in a high frequency circuit based on silicon substrate is significantly enhanced, thereby enhancing the characteristics of the overall system IC, enabling the implementation of a ‘system on a chip (SoC)’ wherein all RF circuits are integrated, and enabling mass production of large diameter ‘integrated passive devices (IPDs)’ and interposers based on a lossy silicon substrate for high frequency package applications.

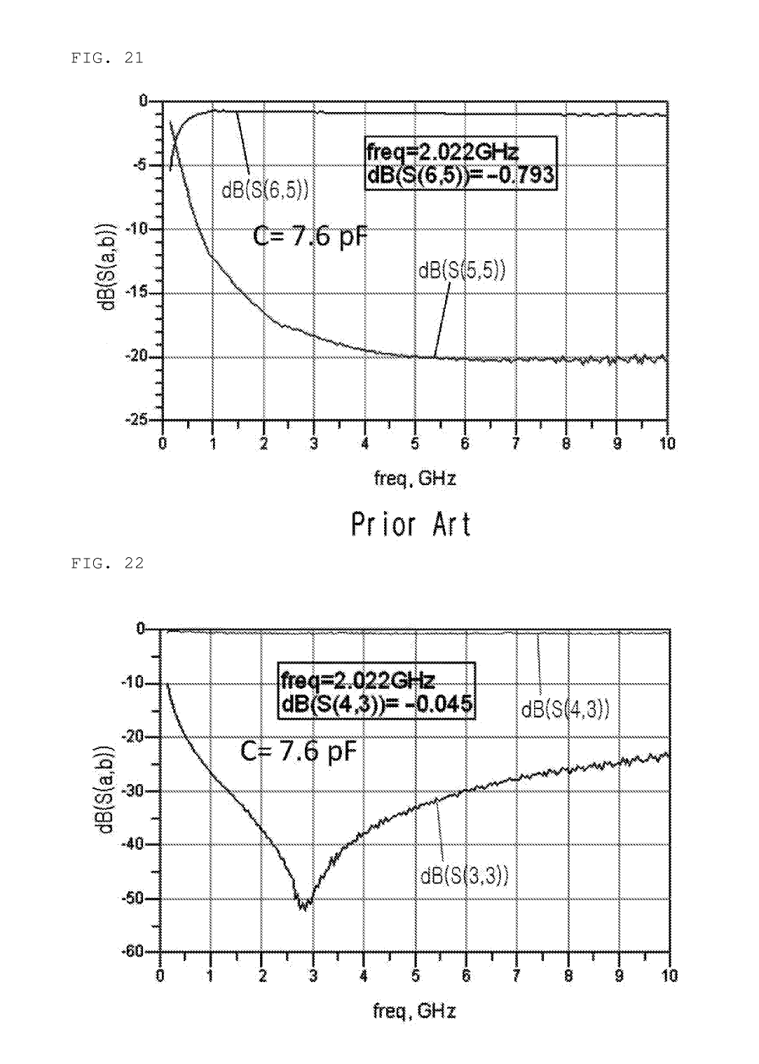

Hereinafter, with reference to FIGS. 21 to 24, the performance characteristics of the capacitor according to an exemplary embodiment of the present invention will be described in comparison with those of the capacitors of the prior art.

Since capacitors, especially, MIM capacitors are mainly used for filtering or cutting off direct current or low frequency signal in the circuit, no loss should occur in the capacitor in a frequency range sufficiently high with respect to the capacitance by being recognized as a short circuit. However, for a MIM capacitor integrated in a lossy substrate such as silicon, the electrical loss occurs towards the substrate region located in the lower side of the capacitor in a high frequency range, there is a problem that circuit application thereof is difficult due to the extremely high insertion loss compared to that of a capacitor commonly used.

However, according to an exemplary embodiment of the present invention as previously described in detail, it is verified through the experiment that the insertion loss characteristic of the device can be enhanced at least 10 times for the same capacitance value and the same area in comparison with a capacitor of the prior art, and the results are as follows.

FIGS. 21 and 22 are the graphs comparing the experimental values of scattering parameters (S-parameter) of a capacitor of the prior art and a capacitor according to an exemplary embodiment of the present invention both having cross-sectional area of 150×150 μm².

As generally known, S-parameter is the most widely used circuit performance indicator in RF field, and represents the ratio of input signal and output signal in frequency domain. For example, S(2,1) represents the signal ratio between the signal input to port 1 and the signal output from port 2. That is, it is the numerical value representing the amount of signal output from port 2 compared to the amount of signal input to port 1.

First referring to FIG. 21, S-parameters of a capacitor of the prior art are disclosed for a capacitor having cross-sectional area of 150×150 μm² at the frequency of 2.022 GHz. In FIG. 21, dB(S(5,5)) is the reflection coefficient and dB(S(6,5)) is the transmission coefficient.

Next referring to FIG. 22, S-parameters of a capacitor according to an exemplary embodiment of the present invention are disclosed for a capacitor having cross-sectional area of 150×150 μm² at the frequency of 2.022 GHz. In FIG. 22, dB(S(3,3)) is the reflection coefficient and dB(S(4,3)) is the transmission coefficient.

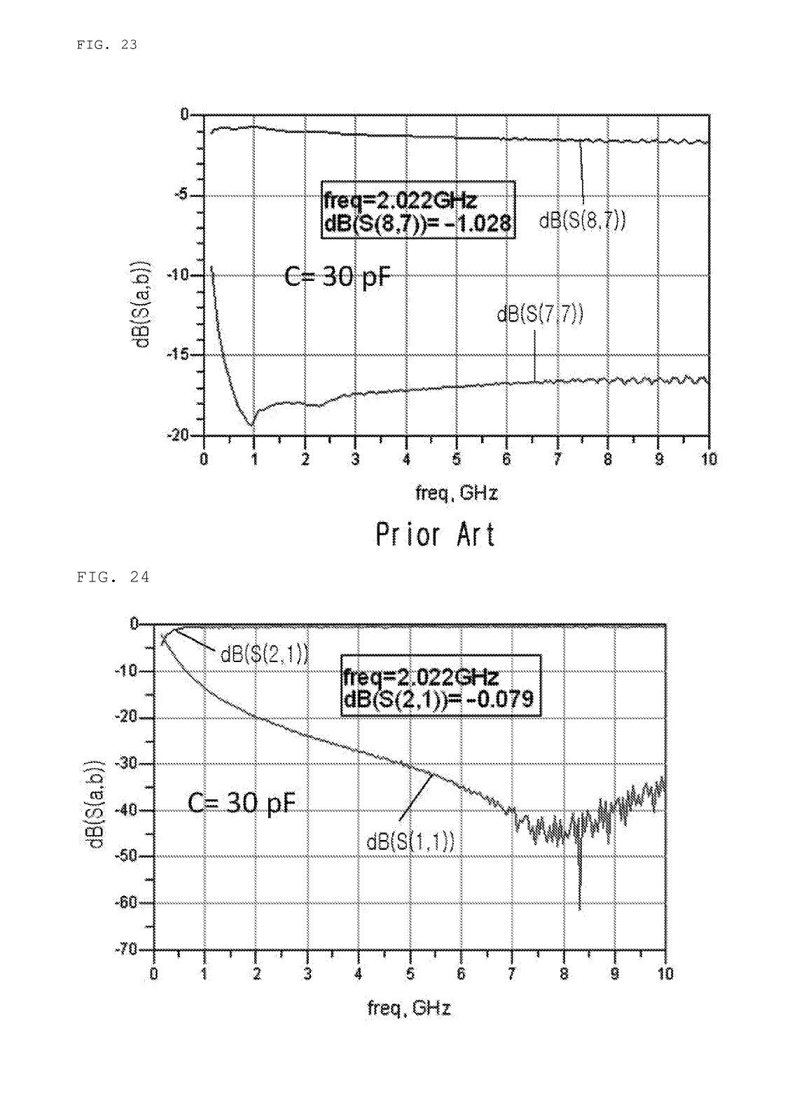

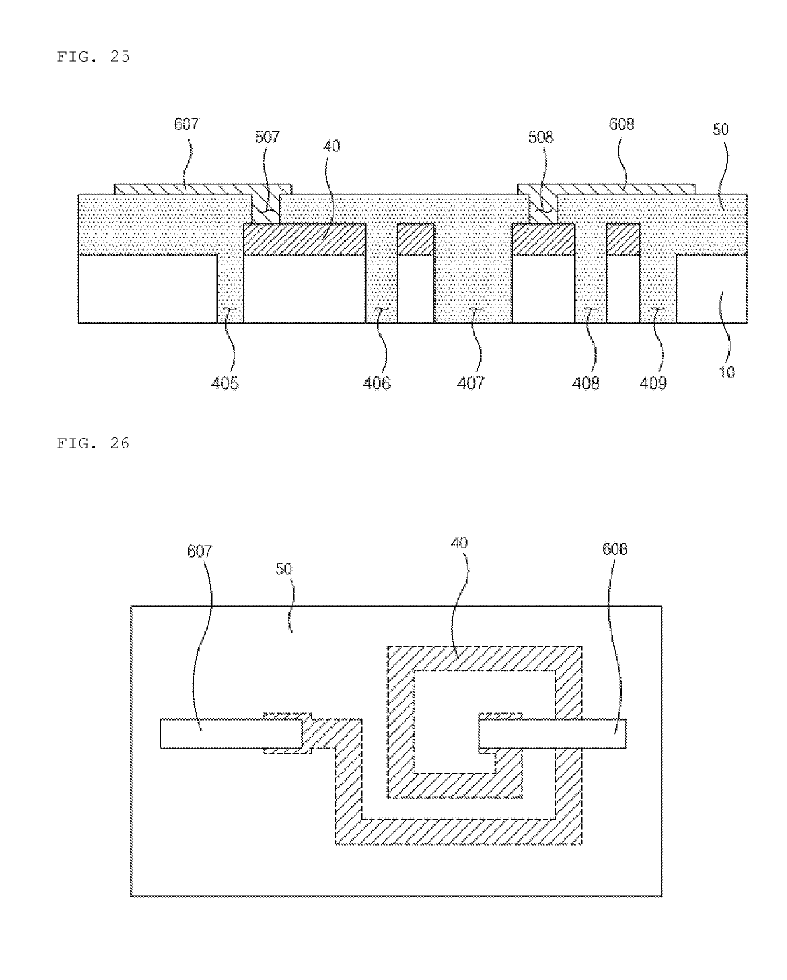

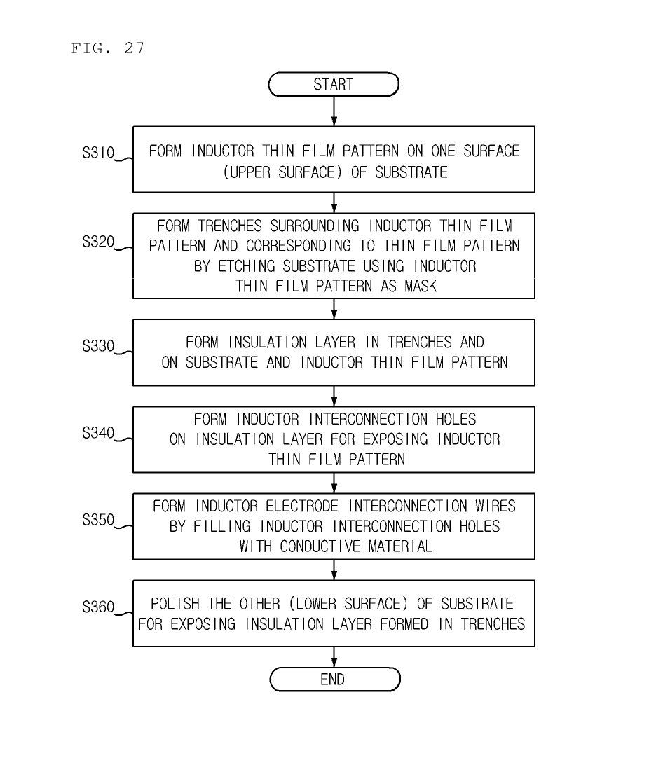

FIGS. 23 and 24 are the graphs comparing the experimental values of S-parameters of a capacitor of the prior art and a capacitor according to an exemplary embodiment of the present invention both having cross-sectional area of 300×300 μm².

First referring to FIG. 23, S-parameters of a capacitor of the prior art are disclosed for a capacitor having cross-sectional area of 300×300 μm² at the frequency of 2.022 GHz. In FIG. 23, dB(S(7,7)) is the reflection coefficient and dB(S(8,7)) is the transmission coefficient.

Next referring to FIG. 24, S-parameters of a capacitor according to an exemplary embodiment of the present invention are disclosed for a capacitor having cross-sectional area of 300×300 μm²at the frequency of 2.022 GHz. In FIG. 24, dB(S(1,1)) is the reflection coefficient and dB(S(2,1)) is the transmission coefficient.

As previously described in detail, according to the present invention, since it has a structure wherein the insulation layer 50 formed in the trenches 402, 404, 406, 408 is exposed by polishing the lower surface of the substrate 10, that is, the opposite side surface facing the upper surface of the substrate 10 wherein the passive device is being formed, the electrical loss can be cut off by fundamentally blocking the path of electrical leakage towards the neighboring unit devices; and accordingly, there is an effect of greatly enhancing the electrical characteristics of the passive device, which is a final product, in a high frequency region.

Moreover, there is an effect of providing a passive device and a manufacturing method thereof, wherein the electrical loss characteristic of a passive device in a high frequency circuit based on silicon substrate is significantly enhanced, thereby enhancing the characteristics of the overall system IC.

Furthermore, there is an effect of providing a passive device and a manufacturing method thereof which enables the implementation of a ‘system on a chip (SoC)’ wherein all RF circuits are integrated.

Furthermore, there is an effect of providing a passive device and a manufacturing method thereof which enables mass production of large diameter ‘integrated passive devices (IPDs)’ and interposers based on a lossy silicon substrate for high frequency package applications.

FIG. 25 is a cross-sectional view of an inductor according to an exemplary embodiment of the present invention; and FIG. 26 is a plan view of an inductor according to an exemplary embodiment of the present invention.

Referring to FIGS. 25 and 26, an inductor according to an exemplary embodiment of the present invention includes: a substrate 10, an inductor thin film pattern 40, a plurality of trenches 405, 406, 407, 408, 409, an insulation layer 50, and a plurality of inductor electrode interconnection wires 607, 608.

The substrate 10 may be a substrate of a silicon material having lossy characteristics. Although a silicon substrate having lossy characteristics has a low electrical isolation coefficient, it is commonly used due to the merits in the aspects of cost. According to the inductor structure of the prior art, the electrical performance thereof is degraded when the inductor is integrated in a silicon substrate having lossy characteristics. However, according to an exemplary embodiment of the present invention, since the silicon substrate 10 having lossy characteristics has a perfect isolation structure, the electrical performance of the inductor can be significantly enhanced while the merit in the aspects of cost is being maintained at the same time. The perfect isolation structure will be described later. The upper surface of the substrate 10 is the surface wherein an inductor thin film pattern 40 which will be described later is being formed, while the lower surface of the substrate 10 is the opposite surface facing the upper surface of the substrate 10. The lower surface of the substrate 10 is being polished so that the insulation layer 50 formed in the trenches 405, 406, 407, 408, 409, which will be described later, is exposed.

Although it is not shown in the drawings herein, for example, an inductor according to an exemplary embodiment of the present invention may further include a lower insulation layer formed between the upper surface of the substrate and the inductor thin film pattern 40, and such lower insulation layer performs the function of reducing the electrical loss of the silicon having lossy characteristics. For example, such lower insulation layer may be a silicon dioxide (SiO₂) or a silicon nitride (SiNₓ), and may be formed to have a thickness less than few microns considering the process unit cost and the wafer bending. Such lower insulation layer is an optional element. That is, even without the lower insulation layer, as described hereinafter, a plurality of trenches 405, 406, 407, 408, 409 are formed in the substrate 10; and after forming an insulation layer 50 in the trenches 405, 406, 407, 408, 409, the lower surface of the substrate 10 is polished in a way that the insulation layer 50 having formed in the trenches 405, 406, 407, 408, 409 is exposed; so that the electrical loss can be cut off by blocking the path of electrical leakage towards the neighboring unit devices; and accordingly, the electrical characteristics, including Q-factor in the high frequency region, of the inductor, which is a final product, are greatly enhanced.

The inductor thin film pattern 40 is formed on the upper of the substrate 10.

For example, such inductor thin film pattern 40 may be a metallic material having the shape of a spiral. The width and the length and the like of the inductor thin film pattern 40 may be determined considering the desired inductance.

The trenches 405, 406, 407, 408, 409 are formed in the substrate 10 surrounding the inductor thin film pattern 40 and corresponding to the inductor thin film pattern 40. More specifically, when a spiral type inductor thin film pattern 40 is formed on the upper surface of the substrate 10, the substrate areas are being etched except the areas of the substrate located under the inductor thin film pattern 40, and these etched areas constitute the trenches 405, 406, 407, 408, 409.

For example, the trenches 405, 406, 407, 408, 409 may be formed by etching the substrate 10 using the inductor thin film pattern 40 as a mask.

The insulation layer 50 is formed in the trenches and on the substrate 10 and the inductor thin film pattern 40. More specifically, the insulation layer 50 is formed to cover one side of the substrate 10 and the inductor thin film pattern 40 as it fills the trenches 405, 406, 407, 408, 409. Inductor interconnection holes 507, 508 are formed in the insulation layer for exposing a portion of the inductor thin film pattern 40.

The inductor electrode interconnection wires 607, 608, which are the electrical connection means, are connected to the inductor thin film pattern 40, and may be formed by filling the inductor interconnection holes 507, 508 with a conductive material.

An inductor according to an exemplary embodiment of the present invention has a structure wherein the insulation layer 50 formed in the trenches 405, 406, 407, 408, 409 is exposed through polishing of the lower surface, that is, the opposite surface facing the upper surface of the substrate 10 wherein the inductor thin film pattern 40 is formed. According to such structure, since the substrate 10 has a full isolation structure, the electrical loss can be cut off by fundamentally blocking the path of electrical leakage towards the neighboring unit devices, thus, the electrical characteristics in a high frequency region are greatly enhanced. Besides, the level of the electrical performance, including Q factor, of the inductor manufactured in a low price lossy silicon substrate can be similarly maintained to that of the passive device manufactured in the relatively expensive semi-insulating substrate such as a GaAs substrate. In addition, the electrical loss characteristic of a capacitor in a high frequency circuit based on silicon substrate is significantly enhanced, thereby enhancing the characteristics of the overall system IC, enabling the implementation of a ‘system on a chip (SoC)’ wherein all RF circuits are integrated, and enabling mass production of large diameter ‘integrated passive devices (IPDs)’ and interposers based on a lossy silicon substrate for high frequency package applications.

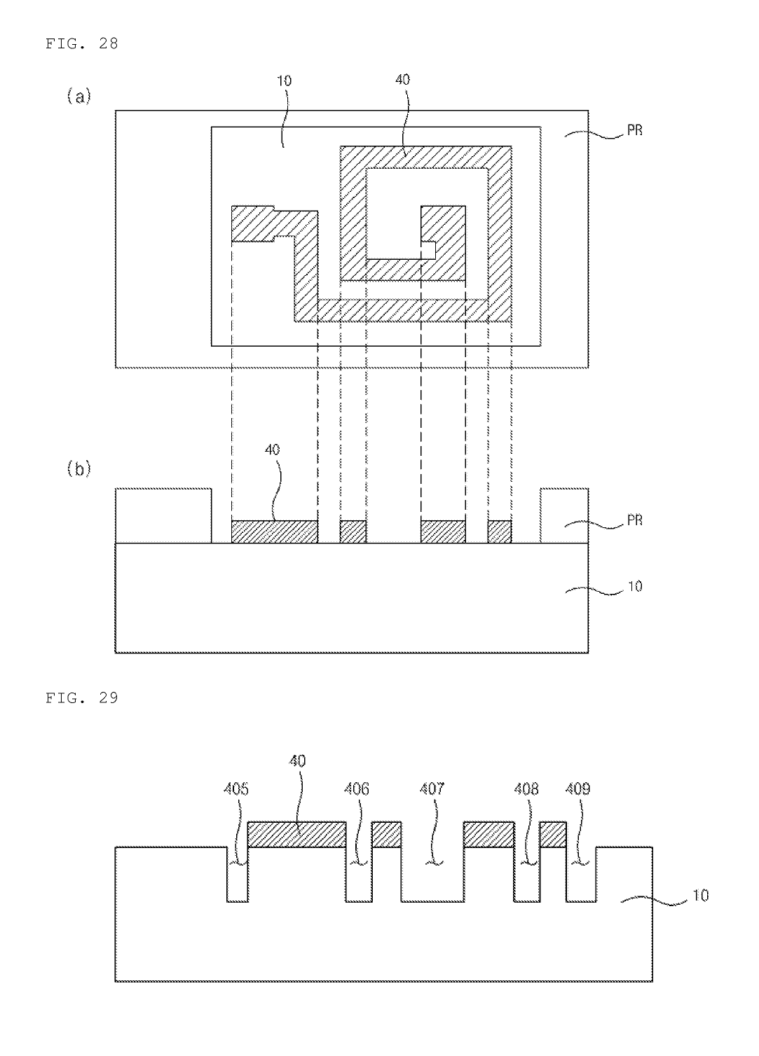

FIG. 27 is a process flow diagram of a method for manufacturing an inductor according to an exemplary embodiment of the present invention; and FIGS. 28 to 33 are the cross-sectional views illustrating the processes of a method for manufacturing an inductor according to an exemplary embodiment of the present invention.

Referring to FIG. 27, a method for manufacturing an inductor according to an exemplary embodiment of the present invention includes the steps of: S310 for forming a thin film pattern, S320 for forming a plurality of trenches, S330 for forming an insulation layer, S340 for forming a plurality of interconnection holes, S350 for forming a plurality of electrode interconnection wires, and S360 for substrate polishing.

Further referring to FIG. 28, in step S310 for forming a thin film pattern, forming process of an inductor thin film pattern 40 on the upper surface of the substrate 10 is performed.

For example, the inductor thin film pattern 40 may be a metallic material having the shape of a spiral. In addition, for example, the width, length, and the like of the inductor thin film pattern 40 may be determined considering the desired inductance.

For example, the substrate 10 may be a substrate of a silicon material having lossy characteristics. The upper surface of the substrate 10 is the surface wherein an inductor thin film pattern 40 is being formed, while the lower surface of the substrate 10 is the opposite surface facing the upper surface.

Although it is not shown in the drawings, for example, before forming the inductor thin film pattern 40, process for forming a lower insulation layer in the upper surface of the substrate 10 may be performed. Such lower insulation layer performs the function of reducing the electrical loss of the silicon having lossy characteristics. For example, such lower insulation layer may be a silicon dioxide (SiO₂) or a silicon nitride (SiNₓ), and may be formed to have a thickness less than few microns considering the process unit cost and the wafer bending. Such lower insulation layer is an optional element. That is, even without the lower insulation layer, as described hereinafter, a plurality of trenches are formed in the substrate 10; and after filling the trenches with an insulation layer 50, the lower surface of the substrate 10 is polished in a way that the insulation layer 50 having been filled in the trenches is exposed; so that the electrical loss can be cut off by blocking the path of electrical leakage towards the neighboring unit devices; and accordingly, the electrical characteristics of the inductor, which is a final product, are greatly enhanced in the high frequency region.

Further referring to FIG. 29, in step S320 for forming a plurality of trenches, forming process of trenches 405, 406, 407, 408, 409, which surround the inductor thin film pattern 40 and correspond to the inductor thin film pattern 40, in the substrate 10 is performed by etching the substrate 10 using the inductor thin film pattern 40 as a mask.

More specifically, when a spiral type inductor thin film pattern 40 is formed on the upper surface of the substrate 10, the substrate areas are being etched except the areas of the substrate located under the inductor thin film pattern 40, and these etched areas constitute the trenches 405, 406, 407, 408, 409.

For example, the trenches 405, 406, 407, 408, 409 may be formed by etching the substrate 10 using the inductor thin film pattern 40 and photoresist (PR) formed in the perimeter of the inductor thin film pattern 40 as masks. According to this process, the outer boundary of the trenches 405, 406, 407, 408, 409 is defined by the photoresist, and it surrounds the inductor thin film pattern 40 and has a shape corresponding to the inductor thin film pattern 40.

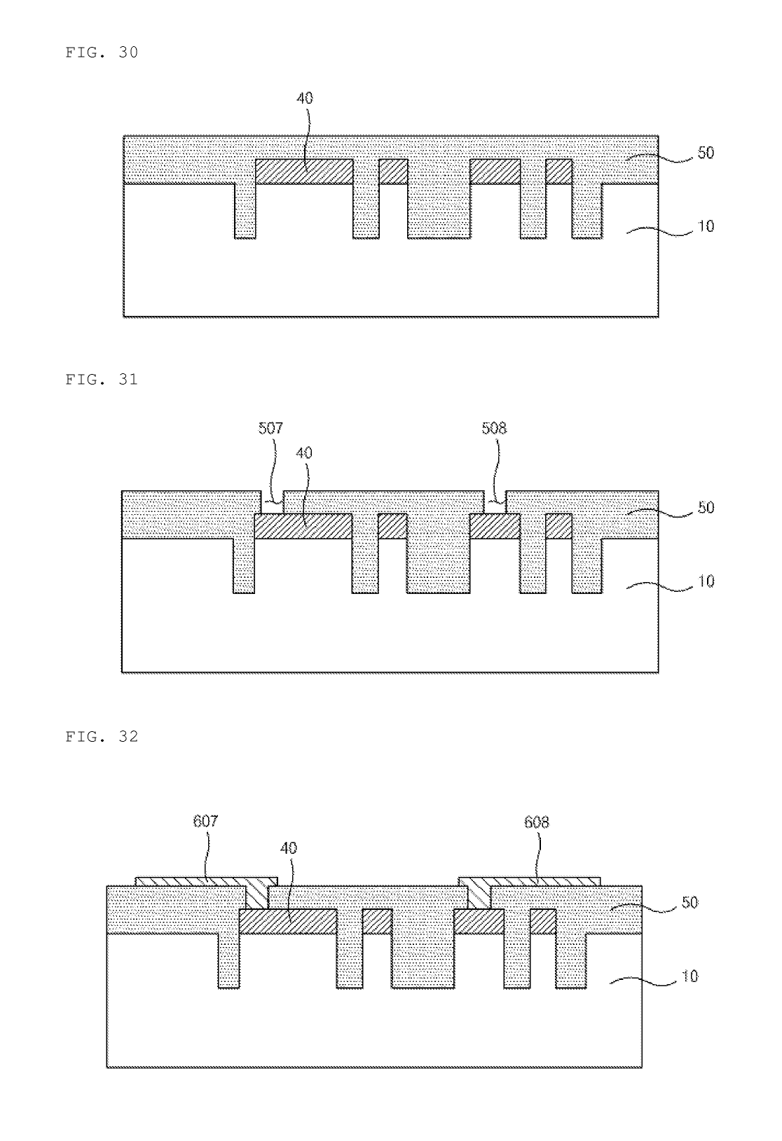

Further referring to FIG. 30, in step S330 for forming an insulation layer, forming process of the insulation layer 50 in the trenches 405, 406, 407, 408, 409 and on the substrate 10 and the inductor thin film pattern 40, is performed. More specifically, the insulation layer 50 is formed to fill the trenches 405, 406, 407, 408, 409 and cover the upper surface of the substrate 10 and the inductor thin film pattern 40.

For example, in step S330 for forming an insulation layer, the insulation layer 50 may be formed using a method of organic lamination, spin coating, molding, or screen printing. Especially, when the insulation layer 50 is formed by a method of lamination, it has an advantage in the aspects of cost.

Further referring to FIG. 31, in step S340 for forming interconnection holes, forming process of the inductor interconnection holes 507, 508 is performed so that the inductor thin film pattern 40 is exposed through the insulation layer 50.

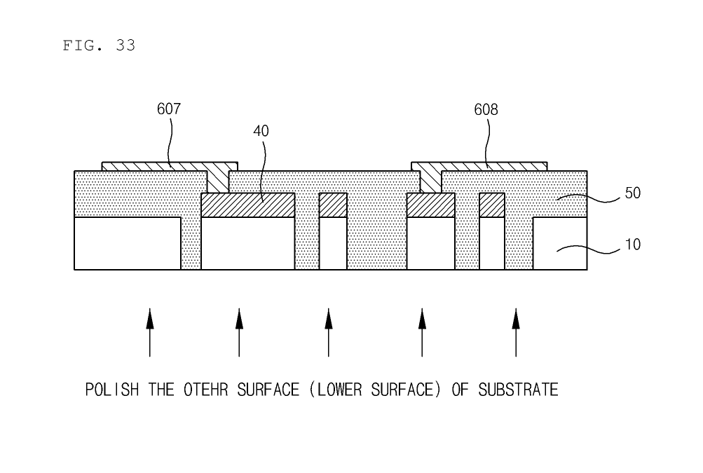

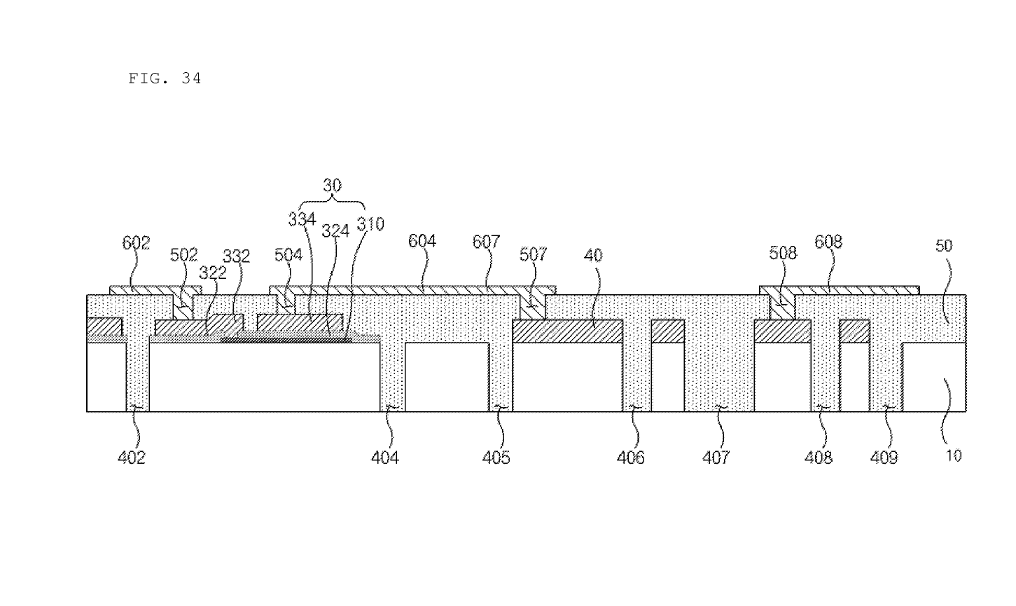

Further referring to FIG. 32, in step S350 for forming electrode interconnection wires, forming process of the inductor electrode interconnection wires 607, 608, which are electrical connection means, is performed by filling the inductor interconnection holes 507, 508 with a conductive material.

Further referring to FIG. 33, in step S360 for substrate polishing, polishing process of the lower surface of the substrate 10 is performed so that the insulation layer 50 formed in the trenches 405, 406, 407, 408, 409, is exposed. This process may be performed by a chemical polishing or a mechanical polishing.

Once the above described method for manufacturing an inductor according to an exemplary embodiment of the present invention is performed, a structure is obtained wherein the insulation layer 50 formed in the trenches 405, 406, 407, 408, 409, is exposed through polishing of the lower surface of the substrate 10, that is, the opposite surface facing the upper surface of the substrate 10 wherein the capacitor thin film pattern 30 is formed. According to such structure, the electrical loss can be cut off by fundamentally blocking the path of electrical leakage towards the neighboring unit devices; and accordingly, the electrical characteristics of an inductor, which is a final product, are greatly enhanced. Besides, the level of the electrical performance, including Q factor, of the inductor manufactured in a low price lossy silicon substrate can be similarly maintained to that of the passive device manufactured in the relatively expensive semi-insulating substrate such as a GaAs substrate. More specifically, the electrical loss characteristic of the inductor in a high frequency circuit based on silicon substrate is significantly enhanced, thereby enhancing the characteristics of the overall system IC, enabling the implementation of a ‘system on a chip (SoC)’ wherein all RF circuits are integrated, and enabling mass production of large diameter ‘integrated passive devices (IPDs)’ and interposers based on a lossy silicon substrate for high frequency package applications. In addition, the electrical characteristics of the inductor may be effectively enhanced through the simple processes of forming trenches and forming insulation layer, and substrate polishing.

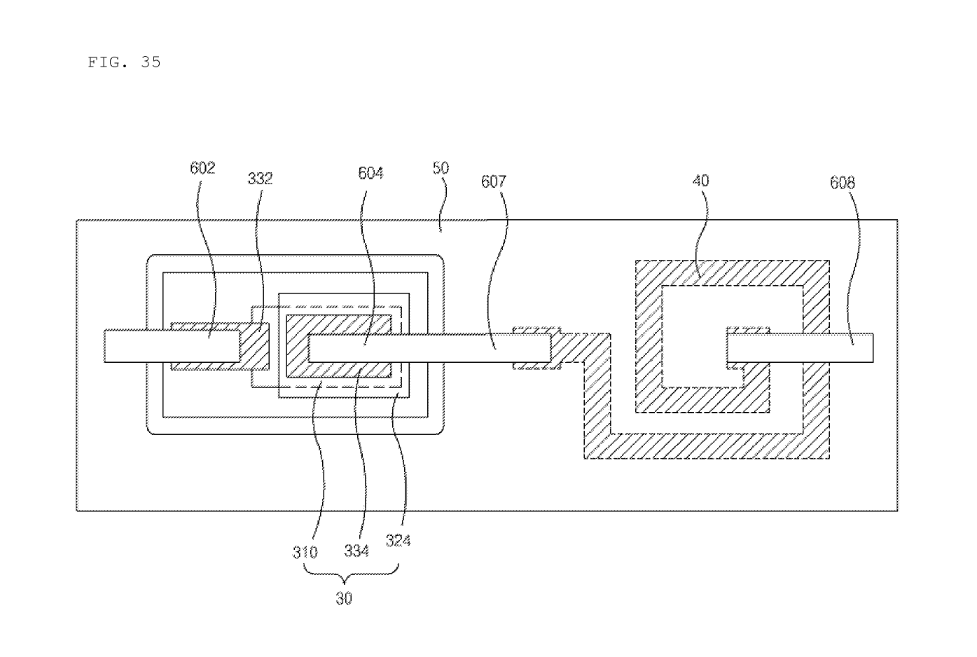

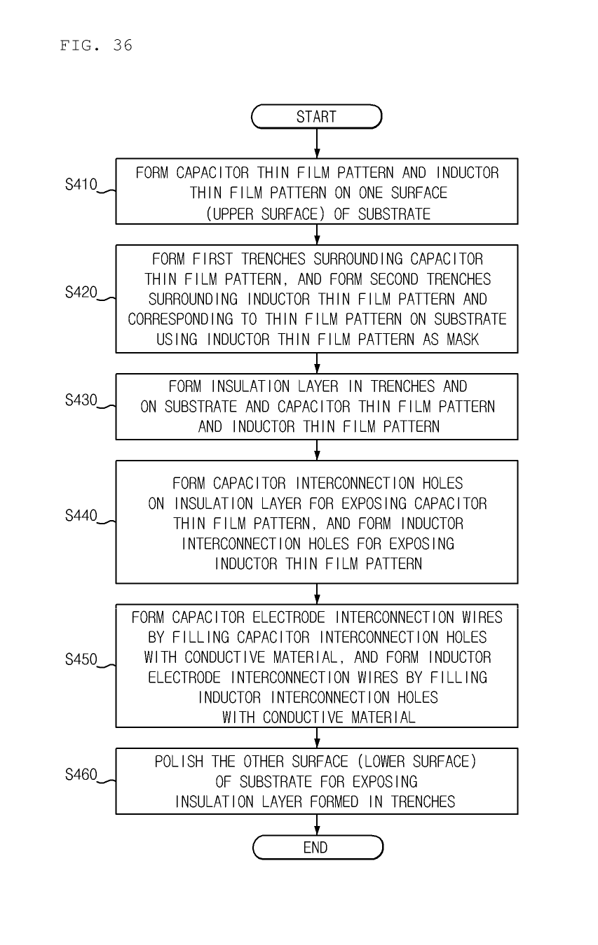

FIG. 34 is a cross-sectional view of a passive device including a capacitor and an inductor according to the second exemplary embodiment of the present invention; and FIG. 35 is a plan view of a passive device including a capacitor and an inductor according to the second exemplary embodiment of the present invention.

Referring to FIGS. 34 and 35, a passive device including a capacitor and an inductor according to the second exemplary embodiment of the present invention includes: a substrate 10, a capacitor thin film pattern 30, an inductor thin film pattern 40, a plurality of trenches 402, 404, 405, 406, 407, 408, 409, an insulation layer 50, a plurality of capacitor interconnection wires 602, 604, and a plurality of inductor interconnection wires 607, 608.

The substrate 10 may be a substrate of a silicon material having lossy characteristics. Although a silicon substrate having lossy characteristics has a low electrical isolation coefficient, it is commonly used due to the merits in the aspects of cost. According to the passive device of the prior art, the electrical performance thereof is degraded when the passive device is integrated in a silicon substrate having lossy characteristics. However, according to an exemplary embodiment of the present invention, since the silicon substrate 10 having lossy characteristics has a perfect isolation structure, the electrical performance of the passive device can be significantly enhanced while the merit in the aspects of cost is being maintained at the same time. The perfect isolation structure will be described later. The upper surface of the substrate 10 is the surface wherein an inductor thin film pattern 40 which will be described later is being formed, while the lower surface of the substrate 10 is the opposite surface facing the one surface of the substrate 10. The lower surface of the substrate 10 is being polished so that the insulation layer 50 formed in the trenches 402, 404, 405, 406, 407, 408, 409, which will be described later, is exposed.

Although it is not shown in the drawings herein, for example, a passive device including a capacitor and an inductor according to an exemplary embodiment of the present invention may further include a lower insulation layer formed between the upper surface of the substrate and the inductor thin film pattern 40, and such lower insulation layer performs the function of reducing the electrical loss of the silicon having lossy characteristics. For example, such lower insulation layer may be a silicon dioxide (SiO₂) or a silicon nitride (SiNₓ), and may be formed to have a thickness less than few microns considering the process unit cost and the wafer bending. Such lower insulation layer is an optional element. That is, even without the lower insulation layer, as described hereinafter, a plurality of trenches 402, 404, 405, 406, 407, 408, 409, are formed in the substrate 10; and after forming an insulation layer 50 in the trenches 402, 404, 405, 406, 407, 408, 409, the lower surface of the substrate 10 is polished in a way that the insulation layer 50 having formed in the trenches 402, 404, 405, 406, 407, 408, 409 is exposed; so that the electrical loss can be cut off by blocking the path of electrical leakage towards the neighboring unit devices; and accordingly, the electrical characteristics, including Q-factor in the high frequency region, of the passive device including a capacitor and an inductor, which is a final product, are greatly enhanced.

The capacitor thin film pattern 30 and the inductor thin film pattern 40 are formed on the upper surface of the substrate 10, and the second metal layer 334 constituting the capacitor thin film pattern 30 and the inductor thin film pattern 40 may be formed at the same time using the same process.

For example, the capacitor thin film pattern 30 may include a first metal layer 310 patterned in the form of a thin film, a capacitor insulation layer 324, and a second metal layer 334. Also, the inductor thin film pattern 40 may be formed in the forming process of the second metal layer together with the second metal layer 334. For example, such inductor thin film pattern 40 may be metallic material having the shape of a spiral. In addition, for example, the width and the length of the inductor thin film pattern 40 may be determined considering the desired inductance.

The trenches 402, 404, 405, 406, 407, 408, 409 include a plurality of first trenches 402, 404 and a plurality of second trenches 405, 406, 407, 408, 409.

The first trenches 402, 404 are formed on the upper surface of the substrate 10 so as to surround the capacitor thin film pattern 30. Since the purpose of the insulation layer 50 being filled in the first trenches 402, 404 is to obtain the electrical insulation, it becomes more advantageous as the widths of the first trenches 402, 404 are getting wider. For example, for a few GHz application range, a sufficient insulation can be obtained if the width of the trench is wider than about 10 μm.

The second trenches 405, 406, 407, 408, 409 are formed in the substrate 10 surrounding the inductor thin film pattern 40 and corresponding to the inductor thin film pattern 40. More specifically, when a spiral type inductor thin film pattern 40 is formed on the upper surface of the substrate 10, the substrate areas are being etched except the areas of the substrate located under the inductor thin film pattern 40, and these etched areas constitute the second trenches 405, 406, 407, 408, 409.

For example, the first trenches 402, 404 may be formed by etching the substrate 10 using the capacitor thin film pattern 30 as a mask, and the second trenches 405, 406, 407, 408, 409 may be formed by etching the substrate 10 using the inductor thin film pattern 40 as a mask.

The insulation layer 50 is formed in the trenches 402, 404, 405, 406, 407, 408, 409 and on the substrate 10, the capacitor thin film pattern 30, and the inductor thin film pattern 40. More specifically, the insulation layer 50 is formed in the trenches and on the substrate 10 and the inductor thin film pattern 40. More specifically, the insulation layer 50 is formed to cover one side of the substrate 10 and the inductor thin film pattern 40 as it fills the trenches 405, 406, 407, 408, 409. Inductor interconnection holes 507, 508 are formed in the insulation layer for exposing a portion of the inductor thin film pattern 40.

The capacitor interconnection wires 602, 604, which are the electrical connection means, are connected to the capacitor thin film pattern 30, and may be formed by filling the capacitor interconnection holes 502, 504 with a conductive material. And, the inductor electrode interconnection wires 607, 608, which are the electrical connection means, are connected to the inductor thin film pattern 40, and may be formed by filling the inductor interconnection holes 507, 508 with a conductive material.

For example, the capacitor electrode interconnection wire 604 electrically connected to the second metal layer 334 and the inductor electrode interconnection wire 607 electrically connected to the one end of the inductor thin film pattern 40 may be formed as a single element.

A passive device including a capacitor and an inductor according to the second exemplary embodiment of the present invention has a structure wherein the insulation layer 50 formed in the trenches 402, 404, 405, 406, 407, 408, 409 is exposed through polishing of the lower surface, that is, the opposite surface facing the upper surface of the substrate 10 wherein the capacitor thin film pattern 30 and the inductor thin film pattern 40 are formed. According to such structure, since the substrate 10 has a full isolation structure, the electrical loss can be cut off by fundamentally blocking the path of electrical leakage towards the neighboring unit devices, thus, the electrical characteristics in a high frequency region are greatly enhanced. Besides, the level of the electrical performance, including Q factor, of the passive device including a capacitor and an inductor manufactured in a low price lossy silicon substrate can be similarly maintained to that of the passive device manufactured in the relatively expensive semi-insulating substrate such as a GaAs substrate. In addition, the electrical loss characteristic of a passive device in a high frequency circuit based on silicon substrate is significantly enhanced, thereby enhancing the characteristics of the overall system IC, enabling the implementation of a ‘system on a chip (SoC)’ wherein all RF circuits are integrated, and enabling mass production of large diameter ‘integrated passive devices (IPDs)’ and interposers based on a lossy silicon substrate for high frequency package applications.

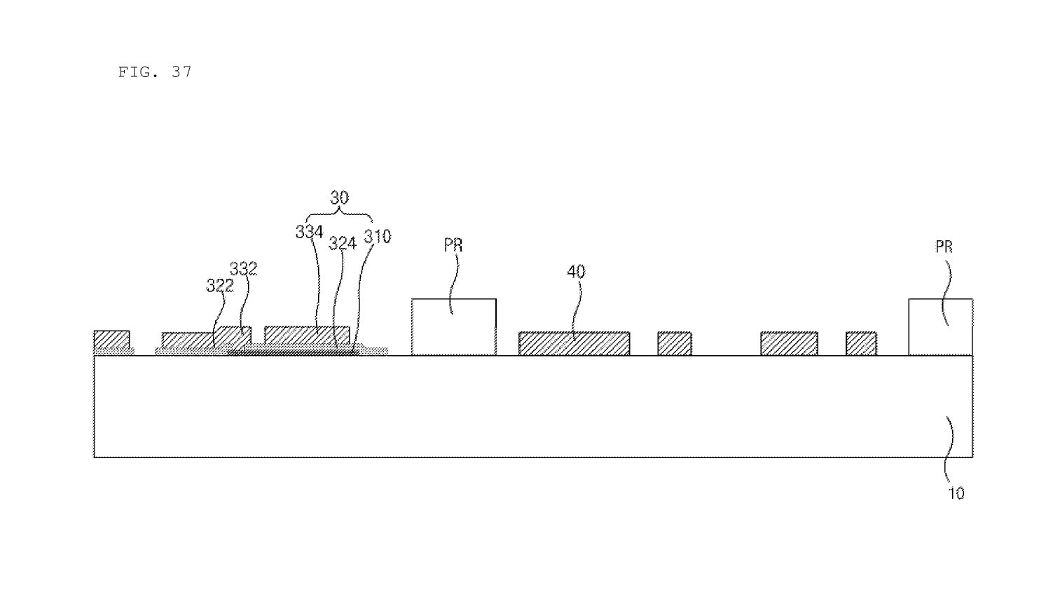

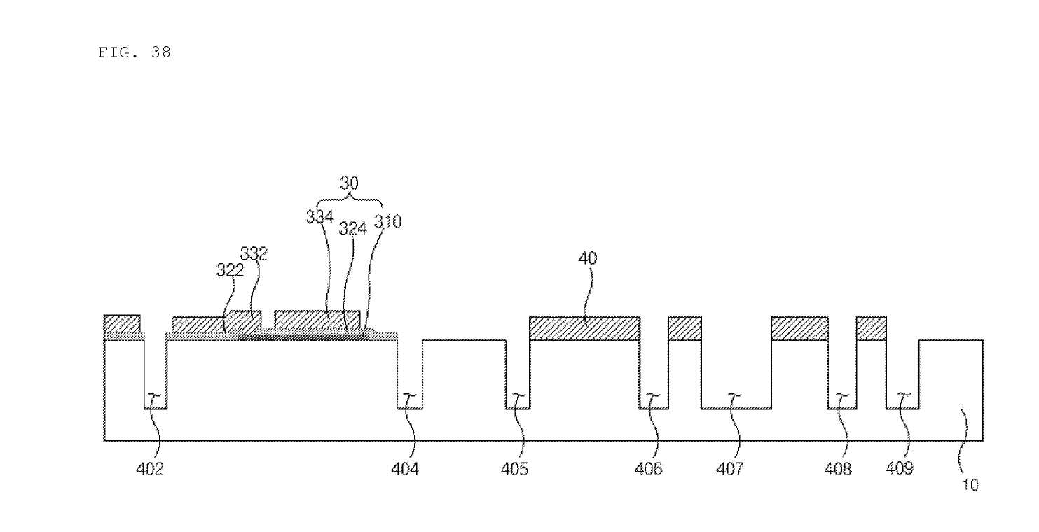

FIG. 36 is a process flow diagram of a method for manufacturing a passive device including a capacitor and an inductor according to the second exemplary embodiment of the present invention; and FIGS. 37 to 42 are the cross-sectional views illustrating the processes of a method for manufacturing a passive device including a capacitor and an inductor according to the second exemplary embodiment of the present invention.

Referring to FIG. 36, a method for manufacturing a passive device including a capacitor and an inductor according to the second exemplary embodiment of the present invention includes the steps of: step S410 for forming a thin film pattern, step S420 for forming a plurality of trenches, step S430 for forming an insulation layer, step S440 for forming a plurality of interconnection holes, step S450 for forming a plurality of electrode interconnection wires, and step S460 for substrate polishing.

Further referring to FIG. 37, in step S410 for forming a thin film pattern, forming process of a capacitor thin film pattern 30 and an inductor thin film pattern 40 on the upper surface of the substrate 10 is performed.

For example, such inductor thin film pattern 40 may be a metallic material having the shape of a spiral. The width and the length and the like of the inductor thin film pattern 40 may be determined considering the desired inductance.

For example, the substrate 10 may be a substrate of a silicon material having lossy characteristics. The upper surface of the substrate 10 is the surface wherein an inductor thin film pattern 40 is being formed, while the lower surface of the substrate 10 is the opposite surface facing the upper surface.

Although it is not shown in the drawings, for example, before forming the inductor thin film pattern 40, process for forming a lower insulation layer in the upper surface of the substrate 10 may be performed. Such lower insulation layer performs the function of reducing the electrical loss of the silicon having lossy characteristics. For example, such lower insulation layer may be a silicon dioxide (SiO₂) or a silicon nitride (SiNₓ), and may be formed to have a thickness less than few microns considering the process unit cost and the wafer bending. Such lower insulation layer is an optional element. That is, even without the lower insulation layer, as described hereinafter, a plurality of trenches 402, 404, 405, 406, 407, 408, 409 are formed in the substrate 10; and after filling the trenches 402, 404, 405, 406, 407, 408, 409 with an insulation layer 50, the lower surface of the substrate 10 is polished in a way that the insulation layer 50 having been filled in the trenches is exposed; so that the electrical loss can be cut off by blocking the path of electrical leakage towards the neighboring unit devices; and accordingly, the electrical characteristics of the passive device including a capacitor and an inductor, which is a final product, are greatly enhanced in the high frequency region.

The capacitor thin film pattern 30 and the inductor thin film pattern 40 are formed on the upper surface of the substrate 10, and these patterns may be formed at the same time using the same process.

For example, the capacitor thin film pattern 30 may include a first metal layer 310 patterned in the form of a thin film, a capacitor insulation layer 324, and a second metal layer 334. Also, the inductor thin film pattern 40 may be formed in the forming process of the second metal layer together with the second metal layer 334. For example, such inductor thin film pattern 40 may be metallic material having the shape of a spiral. In addition, for example, the width and the length of the inductor thin film pattern 40 may be determined considering the desired inductance.

Further referring to FIG. 38, in step S420 for forming a plurality of trenches, forming processes are performed wherein the first trenches 402, 404 surrounding the capacitor thin film pattern 30 are formed on the upper surface of the substrate 10, and the second trenches 405, 406, 407, 408, 409 surrounding the inductor thin film pattern 40 and corresponding to the inductor thin film pattern 40 are formed using the inductor thin film pattern 40 as a mask.

For example, the first trenches 402, 404 surrounding the capacitor thin film pattern 30, and the second trenches 405, 406, 407, 408, 409 surrounding the inductor thin film pattern 40 and corresponding to the inductor thin film pattern 40 may be formed using the same process.

For example, when the spiral type inductor thin film pattern 40 is formed on the upper surface of the substrate, the substrate areas except the substrate areas under the inductor thin film pattern 40 are being etched, and these etched areas constitute the second trenches 405, 406, 407, 408, 409.

For example, the second trenches 405, 406, 407, 408, 409 may be formed by etching the substrate 10 using the inductor thin film pattern 40 and photoresist (PR) formed in the perimeter of the inductor thin film pattern 40 as masks. According to this process, the outer boundary of the second trenches 405, 406, 407, 408, 409 is defined by the photoresist, and it surrounds the inductor thin film pattern 40 and has a shape corresponding to the inductor thin film pattern 40.

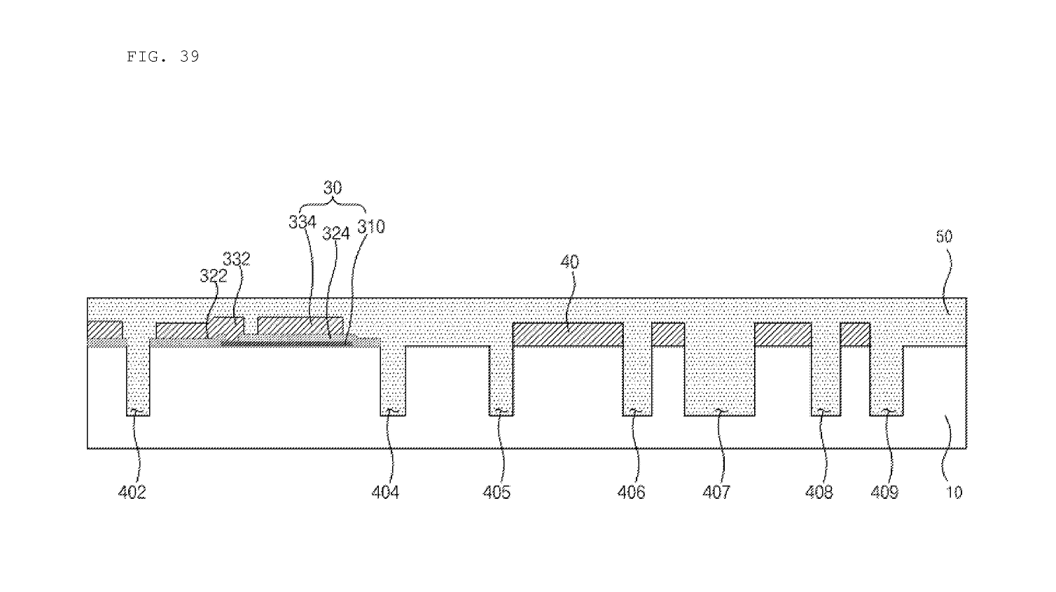

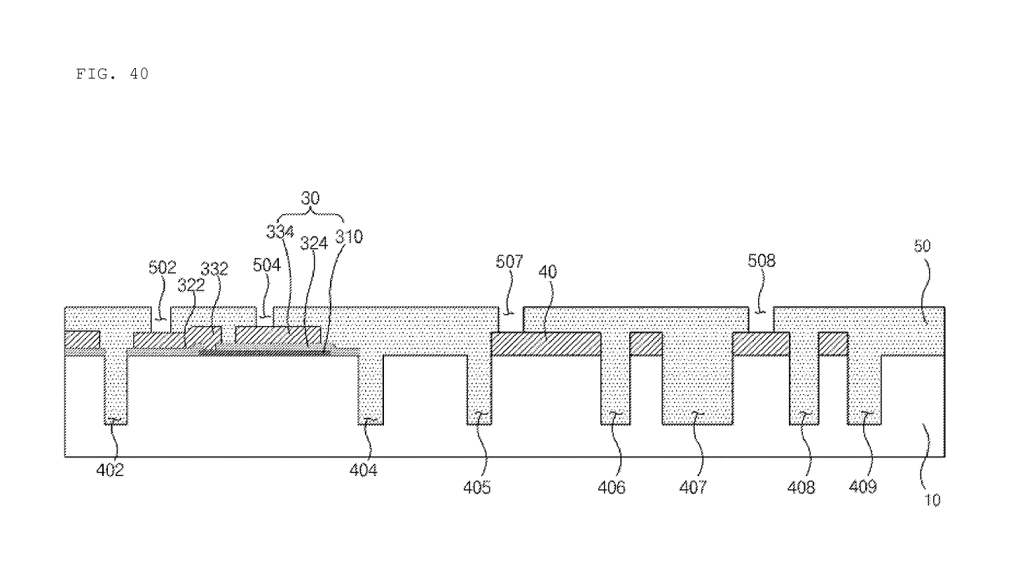

Further referring to FIG. 39, in step S430 for forming an insulation layer, forming process of the insulation layer 50 in the trenches 402, 404, 405, 406, 407, 408, 409 and on the substrate 10 and the inductor thin film pattern 40, is performed. More specifically, the insulation layer 50 is formed to fill the trenches 402, 404, 405, 406, 407, 408, 409 and cover the upper surface of the substrate 10 and the inductor thin film pattern 40.

For example, in step S430 for forming an insulation layer, the insulation layer 50 may be formed using a method of organic lamination, spin coating, molding, or screen printing. Especially, when the insulation layer 50 is formed by a method of lamination, it has an advantage in the aspects of cost.

Further referring to FIG. 40, in step S440 for forming interconnection holes, forming process of the capacitor interconnection holes 502, 504 is performed so that the capacitor thin film pattern 30 is exposed through the insulation layer 50, and forming process of the inductor interconnection holes 507, 508 is performed so that the inductor thin film pattern 40 is exposed through the insulation layer 50.

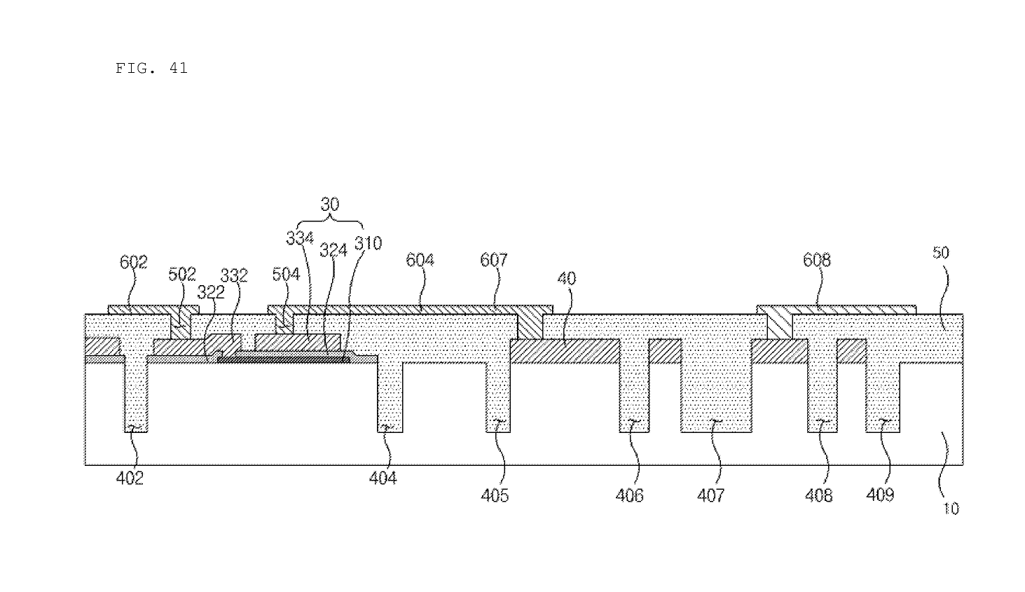

Further referring to FIG. 41, in step S450 for forming a plurality of electrode interconnection wires, forming process of the capacitor electrode interconnection wires 602, 604 is performed by filling the capacitor interconnection holes 502, 504 with a conductive material, and forming process of the inductor electrode interconnection wires 607, 608 is performed by filling the inductor interconnection holes 507, 508 with a conductive material.

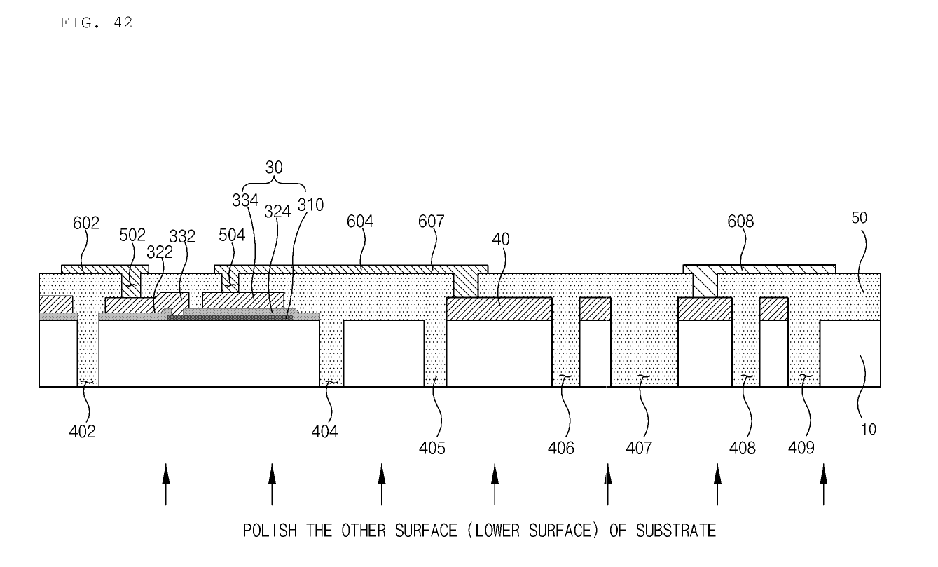

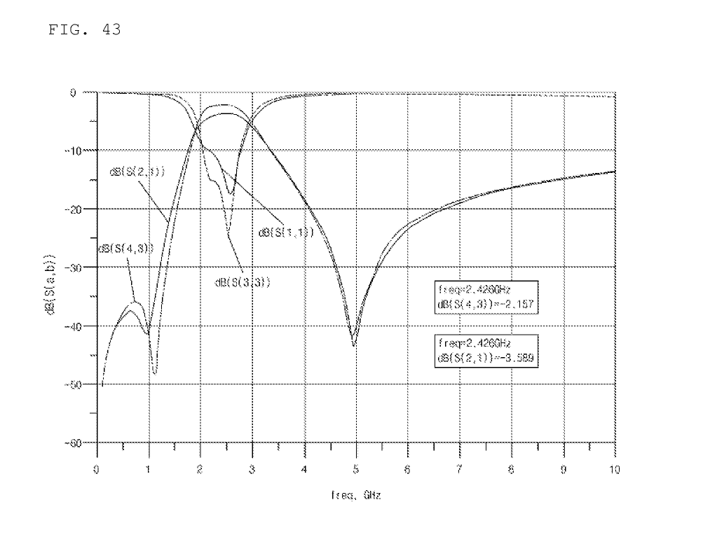

Further referring to FIG. 42, in step S460 for substrate polishing, polishing process of the lower surface of the substrate 10 is performed so that the insulation layer 50 formed in the trenches is exposed. This process may be performed by a chemical polishing or a mechanical polishing.

Once the above described method for manufacturing a passive device including a capacitor and an inductor according to an exemplary embodiment of the present invention is performed, a structure is obtained wherein the insulation layer 50 formed in the trenches 402, 404, 405, 406, 407, 408, 409, is exposed through polishing of the lower surface of the substrate 10, that is, the opposite surface facing the upper surface of the substrate 10 wherein the capacitor thin film pattern 30 and an inductor thin film 40 are formed. According to such structure, since the substrate 10 has a full isolation structure, the electrical loss can be cut off by fundamentally blocking the path of electrical leakage towards the neighboring unit devices, thus, the electrical characteristics in a high frequency region are greatly enhanced. Besides, the level of the electrical performance, including Q factor, of the passive device including a capacitor and an inductor manufactured in a low price lossy silicon substrate can be similarly maintained to that of the passive device manufactured in the relatively expensive semi-insulating substrate such as a GaAs substrate. In addition, the electrical loss characteristic of a passive device in a high frequency circuit based on silicon substrate is significantly enhanced, thereby enhancing the characteristics of the overall system IC, enabling the implementation of a ‘system on a chip (SoC)’ wherein all RF circuits are integrated, and enabling mass production of large diameter ‘integrated passive devices (IPDs)’ and interposers based on a lossy silicon substrate for high frequency package applications. In addition, the electrical characteristics of the passive device including a capacitor and an inductor can effectively enhanced through simple processes of forming trenches, forming insulation layer, and substrate etching.

Hereinafter, with reference to FIG. 43, the performance characteristics of a passive device including a capacitor and an inductor according to the second exemplary embodiment of the present invention will be described in comparison with those of the passive device of the prior art.

FIG. 43 is the graph comparing the experimental values of scattering parameters (S-parameter) of a passive device of the prior art and a passive device including a capacitor and an inductor according to the second exemplary embodiment of the present invention.

As generally known, S-parameter is the most widely used circuit performance indicator in RF field, and represents the ratio of input signal and output signal in frequency domain. For example, S(2,1) represents the signal ratio between the signal input to port 1 and the signal output from port 2. That is, it is the numerical value representing the amount of signal output from port 2 compared to the amount of signal input to port 1.

Referring to FIG. 43, dB(S(1,1)) is the reflection coefficient of a passive device of the prior art, and dB(S(2,1)) is the transmission coefficient of a passive device of the prior art; and dB(S(3,3)) is the reflection coefficient of a passive device including a capacitor and an inductor according to an exemplary embodiment of the present invention, and dB(S(4,3)) is the transmission coefficient of a passive device including a capacitor and an inductor according to an exemplary embodiment of the present invention.

As shown in FIG. 43, for a frequency of 2.426 GHz, dB(S(2,1)), which is the transmission coefficient of the prior art, is measured to be −3.589 dB; and dB(S(4,3)), which is the transmission coefficient of a passive device including a capacitor and an inductor according to an exemplary embodiment of the present invention, is measured to be −2.157 dB. As shown through the results of this experiment, the loss characteristics of the passive device including a capacitor and an inductor according to an exemplary embodiment of the present invention has been enhanced about 1.43 dB compared to that of the passive device of the prior art.

As was described above in detail, according to the present invention, there is an effect of providing a passive device and a manufacturing method thereof, wherein insulation material is filled into the trenches formed in the substrate located in the lower side of the passive device; then, the lower surface of the substrate, that is, the opposite side surface facing the upper surface of the substrate wherein the passive device is formed, is polished until the insulation layer is exposed; and the substrate becomes a fully isolated structure thereby; and the electrical loss is being cut off by fundamentally blocking the path of electrical leakage towards the neighboring devices; and the electrical characteristics in the high frequency region is significantly improved.

Besides, there is an effect of providing a passive device and a manufacturing method thereof, wherein the level of the electrical performance, including Q factor, of the passive device manufactured in a low price lossy silicon substrate can be similarly maintained to that of the passive device manufactured in the expensive semi-insulating substrate such as a GaAs substrate.

Moreover, there is an effect of providing a passive device and a manufacturing method thereof, wherein the electrical loss characteristic of a passive device in a high frequency circuit based on silicon substrate is significantly enhanced, thereby enhancing the characteristics of the overall system IC.

Furthermore, there is an effect of providing a passive device and a manufacturing method thereof which enables the implementation of a ‘system on a chip (SoC)’ wherein all RF circuits are integrated.

Furthermore, there is an effect of providing a passive device and a manufacturing method thereof which enables mass production of large diameter ‘integrated passive devices (IPDs)’ and interposers based on a lossy silicon substrate for high frequency package applications.

What is claimed is:

1. A capacitor comprising:
a capacitor thin film pattern formed on one surface of a substrate;
a plurality of trenches formed by etching the substrate formed with the capacitor thin film pattern so as to define a unit area of the capacitor;
an insulation layer, which fills the trenches, formed with a plurality of capacitor interconnection holes for exposing metal layers formed in the substrate and constituting the capacitor; and
a plurality of capacitor electrode interconnection wires formed by filling the capacitor interconnection holes with a conductive material,
wherein the other surface of the substrate is polished in a way that the insulation layer formed in the trenches is exposed.

2. A method for manufacturing a capacitor, comprising:
forming a capacitor thin film pattern on one surface of a substrate;
forming a plurality of trenches so as to define a unit area of the capacitor by etching the substrate wherein the capacitor thin film pattern is formed;
forming an insulation layer in the trenches and on the substrate;
forming a plurality of interconnection holes on the insulation layer so that the metal layers constituting the capacitor are exposed;
forming a plurality of capacitor electrode interconnection wires by filling the capacitor interconnection holes with a conductive material; and
polishing the other surface of the substrate so that the insulation layer formed in the trenches is exposed.

3. The method for manufacturing a capacitor according to claim 2,
wherein, in the step of forming an insulation layer, the insulation layer is formed in the trenches and on the substrate using a method of organic lamination, spin coating, or chemical vapor deposition.

4. A passive device including a capacitor and an inductor comprising:
a capacitor thin film pattern and a thin film metal pattern for the inductor interconnection wires formed on one surface of a substrate;
a plurality of trenches formed by etching the substrate whereat the capacitor thin film pattern and the thin film metal pattern are formed so that the unit areas of the capacitor and the inductor are defined thereby;
an insulation layer which fills the trenches and formed on the substrate, wherein a plurality of capacitor interconnection holes for exposing the metal layers constituting the capacitor and a plurality of inductor interconnection holes for exposing the thin film metal pattern for the inductor interconnection wires are formed;
a plurality of capacitor electrode interconnection wires formed by filling the capacitor interconnection holes formed in the insulation layer with a conductive material; and
an inductor thin film pattern comprising conductive material formed on a top surface of the insulation layer and in the inductor interconnection holes formed in the insulation layer,
wherein the other surface of the substrate is polished so that the insulation layer formed in the trenches is exposed.

5. A method for manufacturing a passive device including a capacitor and an inductor, the method comprising:
forming a capacitor thin film pattern and a thin film metal pattern for the inductor interconnection wires on one surface of a substrate;
forming a plurality of trenches which define unit areas of the capacitor and the inductor by etching the substrate whereat the capacitor thin film pattern and the thin film metal pattern for the inductor interconnection wires are formed;
forming an insulation layer in the trenches and on the substrate;
forming a plurality of capacitor interconnection holes in the insulation layer so that the metal layers constituting the capacitor are exposed and a plurality of inductor interconnection holes in the insulation layer so that the thin film metal pattern for the inductor interconnection wires are exposed;
forming a plurality of capacitor electrode interconnection wires by filling the capacitor interconnection holes with a conductive material;
forming an inductor thin film pattern by filling the inductor interconnection holes in the insulation layer with a conductive material; and
polishing the other surface of the substrate so that the insulation layer formed in the trenches is exposed.

6. An inductor comprising:
an inductor thin film pattern formed on one surface of a substrate;
a plurality of trenches formed in the substrate to surround the inductor thin film pattern and correspond to the inductor thin film pattern; and
an insulation layer formed in the trenches and on the substrate and the inductor thin film pattern,
wherein the other surface of the substrate is polished so that the insulation layer formed in the trenches is exposed.

7. The inductor according to claim 6,
wherein the substrate is a silicon based substrate having lossy characteristics.

8. The inductor according to claim 6,
wherein the inductor thin film pattern has a shape of a spiral.

9. The inductor according to claim 6,
wherein the trenches are formed by etching the substrate using the inductor thin film pattern as a mask.

10. A method for manufacturing an inductor, the method comprising:
forming an inductor thin film pattern on one surface of a substrate;
forming a plurality of trenches in the substrate to surround the inductor thin film pattern and correspond to the inductor thin film pattern by etching the substrate using the inductor thin film pattern as a mask;
forming an insulation layer in the trenches and on the substrate and the inductor thin film pattern; and
polishing the other surface of the substrate so that the insulation layer formed in the trenches is exposed.

11. The method for manufacturing an inductor according to claim 10,
wherein the substrate is a silicon based substrate having lossy characteristics.

12. The method for manufacturing an inductor according to claim 10,
wherein the inductor thin film pattern has a shape of a spiral.

13. The method for manufacturing an inductor according to claim 10,
wherein, in the step of forming the insulation layer, the insulation layer is formed using a method of organic lamination, spin coating, molding, or screen printing.

14. A passive device comprising a capacitor and an inductor, the passive device further comprising:
a capacitor thin film pattern and an inductor thin film pattern formed on one surface of a substrate;
a plurality of trenches including a plurality of first trenches formed on the substrate to surround the capacitor thin film pattern, and a plurality of second trenches formed on the substrate to surround the inductor thin film pattern and correspond to the inductor thin film pattern; and
an insulation layer formed in the trenches and on the substrate, the capacitor thin film pattern and the inductor thin film pattern,
wherein the other surface of the substrate is polished so that the insulation layer formed in the trenches is exposed.

15. The passive device including a capacitor and an inductor according to claim 14,
wherein the substrate is a silicon based substrate having lossy characteristics.

16. The passive device including a capacitor and an inductor according to claim 14,
wherein the inductor thin film pattern has a shape of a spiral.

17. The passive device including a capacitor and an inductor according to claim 14,
wherein the second trenches are formed by etching the substrate using the inductor thin film pattern as a mask.

18. A method for manufacturing a passive device including a capacitor and an inductor, the method comprising:
forming a capacitor thin film pattern and an inductor thin film pattern on one surface of a substrate;
forming a plurality of first trenches surrounding the capacitor thin film pattern in the substrate, and a plurality of second trenches corresponding the inductor thin film pattern and surrounding the inductor thin film pattern using the inductor thin film pattern as a mask;
forming an insulation layer in the trenches and on the substrate, the capacitor thin film pattern and the inductor thin film pattern; and
polishing the other surface of the substrate so that the insulation layer formed in the trenches is exposed.

19. The method for manufacturing a passive device including a capacitor and an inductor according to claim 18,
wherein the substrate is a silicon based substrate having lossy characteristics.

20. The method for manufacturing a passive device including a capacitor and an inductor according to claim 19,
wherein, in the step of forming the insulation layer, the insulation layer is formed using a method of organic lamination, spin coating, molding, or screen printing.
